(19) United States
(12) Patent Application Publication
(10) Pub. No.: US 2023/0209958 A1
(43) Pub. Date: Jun. 29, 2023

(54) DISPLAY DEVICE

(71) Applicant: Samsung Display Co., LTD., Yongin-si (KR)

(72) Inventors: Chang Soon JANG, Seoul (KR); In Ok KIM, Osan-si (KR); Chan Su KIM, Asan-si (KR); Keun Chan OH, Hwaseong-si (KR); Gak Seok LEE, Hwaseong-si (KR); Sang Hun LEE, Hwaseong-si (KR); So Yun LEE, Seoul (KR); Ji Eun JANG, Suwon-si (KR)

(21) Appl. No.: 17/949,847

(22) Filed: Sep. 21, 2022

(30) Foreign Application Priority Data
Dec. 29, 2021 (KR) 10-2021-0190963

(51) Int. Cl. H01L 27/32; H01L 51/52

(52) U.S. Cl. CPC H01L 27/322; H01L 51/5281; H01L 27/3244; G01J 3/28

(57) ABSTRACT

A display device includes a first substrate including a first emission area, a second emission area, and a third emission area, each of which is to emit a first light; a second substrate having a first surface facing the first substrate and a second surface opposite to the first surface; a first color filter, a second color filter and a third color filter, and a first wavelength conversion pattern, a second wavelength conversion pattern and a light-transmitting pattern on the first surface of the second substrate. A thickness of the first color filter is greater than a thickness of the second color filter and the thickness of the second color filter is greater than a thickness of the third color filter.

### CROSS-REFERENCE TO RELATED APPLICATION

This application claims priority to and the benefit of Korean Patent Application No. 10-2021-0190963 filed on Dec. 29, 2021 in the Korean Intellectual Property Office, the content of which is incorporated herein by reference in its entirety.

### BACKGROUND

### 1. Technical Field

The present disclosure relates to a display device.

### 2. Description of the Related Art

Display devices have become more important as multimedia technology has evolved. Accordingly, a variety of display devices such as liquid-crystal display devices (LCDs) and/or organic light-emitting diode display devices (OLEDs) may be utilized in various suitable electronic devices.

Among display devices, a self-luminous display device includes a self-luminous element, for example, an organic light-emitting element. A self-luminous element may include two opposing electrodes (e.g., facing each other) and an emissive layer (e.g., emission layer) interposed therebetween. For an organic light-emitting element as a self-luminous element, electrons and holes supplied from the two electrodes are recombined in the emissive layer to generate excitons, and the generated excitons relax from the excited state to the ground state to thereby emit light.

Such a self-luminous display device generally may not utilize a separate light source such as a backlight unit, and thus self-luminous display devices may relatively consume relatively less power, may be relatively light and thin, and may have high-quality characteristics such as relatively wide viewing angles, high luminance and/or contrast, and/or relatively fast response speeds, compared to related art display devices. Accordingly, organic light-emitting display devices are attracting attention as the next generation display device.

### SUMMARY

Aspects according to embodiments of the present disclosure are directed toward a display device capable of realizing a neutral black reflection color.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes: a first substrate including a first emission area, a second emission area, and a third emission area; a first wavelength conversion pattern overlapping the first emission area; a second wavelength conversion pattern overlapping the second emission area; a light-transmitting pattern overlapping the third emission area; a first color filter on the first wavelength conversion pattern; a second color filter on the second wavelength conversion pattern; and a third color filter on the light-transmitting pattern, wherein reflected light caused by a measurement light source emitted to the substrate includes light of a first color having a wavelength ranging from 380 nm to 500 nm, light of a second color having a wavelength ranging from 500 nm to 600 nm, and light of a third color having a wavelength ranging from 600 nm to 780 nm, wherein a reflectance ratio (%) of the light of the first color, a reflectance ratio (%) of the light of the second color, and a reflectance ratio (%) of the light of the third color, which are measured in a specular component included (SCI) mode, are 5.3 to 9.2, 67.6 to 73.6, and 18.3 to 24.7, respectively.

According to an another embodiment of the present disclosure, a display device includes: a first substrate including a first emission area, a second emission area, and a third emission area, each of which is to emit a first light; a second substrate having a first surface facing the first substrate and on which a first light-transmitting area overlapping the first emission area, a second light-transmitting area overlapping the second emission area, and a third light-transmitting area overlapping the third emission area are defined, and a second surface opposite to the first surface; a first color filter on the first surface of the second substrate and overlapping the first light-transmitting area; a second color filter on the first surface of the second substrate and overlapping the second light-transmitting area; a third color filter on the first surface of the second substrate and overlapping the third light-transmitting area; a first wavelength conversion pattern on the first color filter; a second wavelength conversion pattern on the second color filter; and a light-transmitting pattern on the third color filter, wherein reflected light caused by a measurement light source emitted to the first substrate from a side of the second surface includes light of a first color having a wavelength ranging from 380 nm to 500 nm, light of a second color having a wavelength ranging from 500 nm to 600 nm, and light of a third color having a wavelength ranging from 600 nm to 780 nm, wherein a thickness of the first color filter is greater than a thickness of the second color filter and a thickness of the third color filter, wherein a reflectance ratio (%) of the light of the first color, a reflectance ratio (%) of the light of the second color, and a reflectance ratio (%) of the light of the third color, which are measured in a specular component included (SCI) mode, are 5.1 to 8.0, 70.0 to 74.3, and 18.5 to 23.7, respectively, wherein a reflected color of the reflected light has a color difference ΔEab of 3 or less which is measured by a spectrochromometer, and the color difference ΔEab is calculated by Equation 1 below:

ΔEab={(ΔL*)2+(Δa*)2+(Δb*)2}1/2 (1)

where L*, a*, and b* are colorimetric values in CIE 1931 space measured utilizing the spectrochromometer under conditions of an illuminant C and 2° viewing angle.

According to still another embodiment of the present disclosure, a display device includes: a first substrate including a first emission area, a second emission area, and a third emission area, each of which is to emit a first light; a second substrate having a first surface facing the first substrate and on which a first light-transmitting area overlapping the first emission area, a second light-transmitting area overlapping the second emission area, and a third light-transmitting area overlapping the third emission area are defined, and a second surface opposite to the first surface; a first color filter on the first surface of the second substrate and overlapping the first light-transmitting area; a second color filter on the first surface of the second substrate and overlapping the second light-transmitting area; a third color filter on the first surface of the second substrate and overlapping the third light-transmitting area; a first wavelength conversion pattern on the first color filter; a second wavelength conversion pattern on the second color filter; and a light-transmitting pattern on the third color filter, wherein reflected light caused by a measurement light source emitted to the first substrate from a side of the second surface includes light of a first color having a wavelength ranging from 380 nm to 500 nm, light of a second color having a wavelength ranging from 500 nm to 600 nm, and light of a third color having a wavelength ranging from 600 nm to 780 nm, wherein a reflectance (%) of the light of the first color at 460 nm, a reflectance (%) of the light of the second color at 540 nm, and a reflectance (%) of the light of the third color at 640 nm, which are measured in a specular component included (SCI) mode, are 1.8 to 2.2, 1.7 to 2.3, and 2.8 to 3.8, respectively, wherein a reflected color of the reflected light has a color difference ΔEab of 3 or less which is measured by a spectrochromometer, and the color difference ΔEab is calculated by Equation 1 below:

ΔEab={(ΔL*)2+(Δa*)2+(Δb*)2}1/2 (1)

where L*, a*, and b* are colorimetric values in CIE 1931 space measured utilizing the spectrochromometer under conditions of an illuminant C and 2° viewing angle.

It should be noted that the embodiments and/or effects of the present disclosure are not limited to those described above, and other embodiments and/or effects of the present disclosure should be apparent from the following description.

### BRIEF DESCRIPTION OF THE DRAWINGS

The above and other aspects and features of the present disclosure will become more apparent by describing in more detail example embodiments thereof with reference to the attached drawings, in which:

FIG. 1 is a cross-sectional view illustrating a stack structure of a display device according to some embodiments of the present disclosure;

FIG. 2 is a plan view of a display device according to some embodiments of the present disclosure;

FIG. 3 is an enlarged plan view of portion Q1 of FIG. 2, more specifically, a plan view of a display substrate included in the display device of FIG. 2 according to an embodiment;

FIG. 4 is an enlarged plan view of portion Q1 of FIG. 2, more specifically, a plan view of a color conversion substrate included in the display device of FIG. 2 according to an embodiment;

FIG. 5 is a plan view showing a modification of the example shown in FIG. 3;

FIG. 6 is a plan view showing a modification of the example shown in FIG. 4;

FIG. 7 is an enlarged plan view of portion Q3 of FIG. 2;

FIG. 8 is a cross-sectional view of the display device according to some embodiments of the present disclosure, taken along the line X1-X1′ of FIGS. 3 and 4;

FIG. 9 is an enlarged cross-sectional view of part Q4 of FIG. 8;

FIG. 10 is a cross-sectional view showing a modification of the example of the structure shown in FIG. 9;

FIG. 11 is a cross-sectional view of the display device according to some embodiments of the present disclosure, taken along the line X3-X3′ of FIG. 7;

FIG. 12 is a plan view showing a layout of a third color filter on a color conversion substrate of a display device according to some embodiments of the present disclosure;

FIG. 13 is a plan view showing a layout of a first color filter on the color conversion substrate of the display device according to some embodiments of the present disclosure;

FIG. 14 is a plan view showing a layout of a second color filter on the color conversion substrate of the display device according to some embodiments of the present disclosure;

FIG. 15 is a schematic diagram showing reflection of external light by a display device according to an embodiment of the present disclosure;

FIG. 16 is a plan view of a display device according to some embodiments of the present disclosure;

FIG. 17 is an enlarged plan view of portion Q5′ of FIG. 16, more specifically, a plan view of a display substrate included in the display device of FIG. 16;

FIG. 18 is an enlarged plan view of portion Q5′ of FIG. 16, more specifically, a plan view of a color conversion substrate included in the display device of FIG. 16;

FIG. 19 is a cross-sectional view of the display device according to some embodiments of the present disclosure, taken along the line X5-X5′ of FIGS. 17 and 18;

FIG. 20 is a graph showing an SCI reflectance (%) according to a wavelength;

FIG. 21 is a graph of a visibility curve; and

FIG. 22 is a graph obtained by applying the visibility curve of FIG. 21 to the graph of FIG. 20.

### DETAILED DESCRIPTION

Specific structural and functional descriptions of embodiments of the present disclosure disclosed herein are only for illustrative purposes of the embodiments of the present disclosure. The present disclosure may be embodied in many different forms without departing from the spirit and significant characteristics of the present disclosure. Therefore, the embodiments of the present disclosure are disclosed only for illustrative purposes and should not be construed as limiting the present disclosure. That is, the present disclosure is only defined by the scope of the claims, and equivalents thereof.

It should be understood that when an element is referred to as being related to another element such as being “coupled” or “connected” to another element, it can be directly coupled or connected to the other element or intervening elements may be present therebetween. In contrast, it should be understood that when an element is referred to as being related to another element such as being “directly coupled” or “directly connected” to another element, there are no intervening elements present. Other expressions that explain the relationship between elements, such as “between,” “directly between,” “adjacent to,” or “directly adjacent to,” should be construed in the same way.

Throughout the specification, the same reference numerals will refer to the same or like parts.

It should be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” refers to “and/or.” As used herein, the term “and/or” includes any and all combinations of one or more of the associated listed items. It should be further understood that the terms “comprises,” “comprising,” “includes,” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower,” “bottom,” “upper,” and/or “top,” may be used herein to describe one element's relationship to another element as illustrated in the Figures. It should be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The example term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The example terms “below” or “beneath” can, therefore, encompass both an orientation of above and below.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It should be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments are described herein with reference to cross section illustrations that are schematic illustrations of idealized embodiments. As such, variations from the shapes in the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the attached drawings.

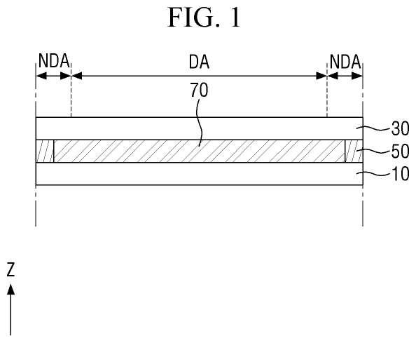

FIG. 1 is a cross-sectional view for illustrating a stack structure of a display device according to some embodiments of the present disclosure.

A display device 1 shown in FIG. 1 may be employed in a variety of electronic devices including small and/or medium sized electronic devices such as a tablet PC, a smartphone, a vehicle navigation unit, a camera, a center information display (CID) installed in vehicles, a wrist-type or kind electronic device (e.g., a smart watch), a personal digital assistant (PMP), a portable multimedia player (PMP), and/or a game machine, and medium and/or large electronic devices such as a television, an electric billboard, a monitor, a personal computer, and/or a laptop computer. It should be understood that the above-listed electronic devices are merely illustrative and the display device 1 may be employed in a variety of other suitable electronic devices without departing from the spirit and scope of embodiments according to the present disclosure.

The display device 1 may include a display area DA where images are displayed and a non-display area NDA in which no images are displayed. In some embodiments, the non-display area NDA may be located around the display area DA to surround it. Images displayed on the display area DA may be seen by a user from the side indicated by the arrow in a third direction Z.

In some embodiments, the stack structure of the display device 1 may include a display substrate 10, and a color conversion substrate 30 facing (e.g., opposed to) the display substrate 10, and may further include a sealing member 50 utilized to couple the display substrate 10 with the color conversion substrate 30, and a filler 70 utilized to fill a space or area between the display substrate 10 and the color conversion substrate 30, as shown in FIG. 1.

The display substrate 10 may include elements and circuits for displaying images, e.g., a pixel circuit such as a switching element, a pixel-defining layer for defining an emission area and a non-emission area to be described in more detail later in the display area DA, and/or a self-luminous element. In some embodiments, the self-light-emitting element may include at least one of an organic light-emitting diode, a quantum-dot light-emitting diode, an inorganic-based micro light-emitting diode (e.g., Micro LED), or an inorganic-based nano light-emitting diode having a nano size (e.g., Nano LED). In the following description, an organic light-emitting diode will be described as an example of the self-luminous element for convenience of illustration, but embodiments according to the present disclosure are not limited thereto.

The color conversion substrate 30 may be located on the display substrate 10 and may face the display substrate 10. In some embodiments, the color conversion substrate 30 may include a color conversion pattern that converts the color of incident light. In some embodiments, the color conversion substrate 30 may include a color filter and/or a wavelength conversion pattern as the color conversion pattern. In some embodiments, the color conversion substrate 30 may include both (e.g., simultaneously) the color filter and the wavelength conversion pattern.

In the non-display area NDA, the sealing member 50 may be located between the color conversion substrate 30 and the display substrate 10. The sealing member 50 may be arranged or formed along the edges of the display substrate 10 and the color conversion substrate 30 in the non-display area NDA to be around (e.g., surround) the display area DA in a plan view. The display substrate 10 and the color conversion substrate 30 may be coupled to each other via the sealing member 50.

In some embodiments, the sealing member 50 may be made of an organic material. For example, the sealing member 50 may be made of, but is not limited to, an epoxy resin. In some other embodiments, the sealing member 50 may be applicable (e.g., deposited) in the form of a frit including glass and/or the like.

The filler 70 may be located in the space between the display substrate 10 and the color conversion substrate 30 surrounded by the sealing member 50. The filler 70 may be utilized to fill the space between the display substrate 10 and the color conversion substrate 30.

In some embodiments, the filler 70 may be made of a light-transmitting material. In some embodiments, the filler 70 may be made of an organic material. For example, the filler 70 may be made of a silicon-based organic material, an epoxy-based organic material, or a mixture of a silicon-based organic material, an epoxy-based organic material, etc.

In some embodiments, the filler 70 may be made of a material having an extinction coefficient of substantially zero. The refractive index and the extinction coefficient are correlated, and thus the refractive index decreases with the extinction coefficient. When the refractive index is 1.7 or less, the extinction coefficient may converge to substantially zero. In some embodiments, the filler 70 may be made of a material having a refractive index of 1.7 or less. Accordingly, it may be possible to prevent or reduce absorption of light provided by the self-luminous element by the filler 70 when passing through the filler 70. In some embodiments, the filler 70 may be made of an organic material having a refractive index of 1.4 to 1.6.

In FIG. 1, the display device 1 is illustrated as including the display substrate 10, the color conversion substrate 30, the sealing member 50, and the filler 70, but according to some embodiments, the sealing member 50 and the filler 70 may be omitted (e.g., may not be included) and elements of the color conversion substrate 30 excluding (e.g., without) a second base 310 may be disposed on the display substrate 10.

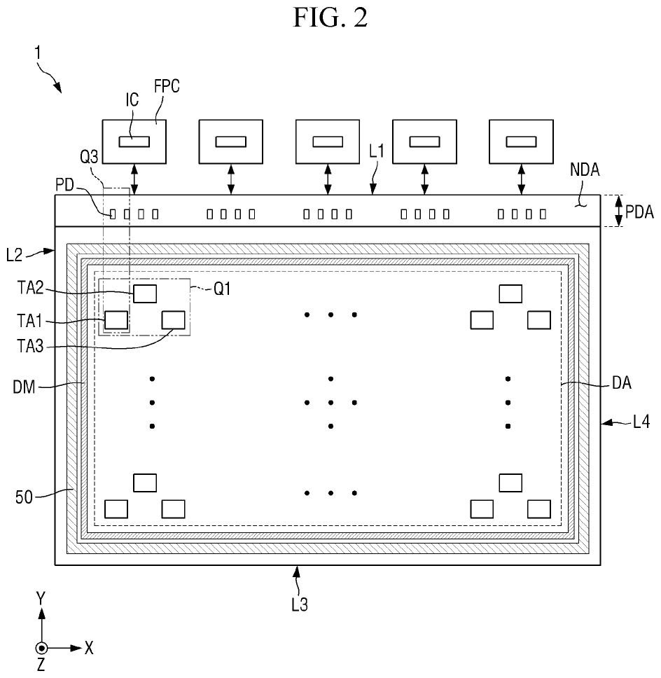

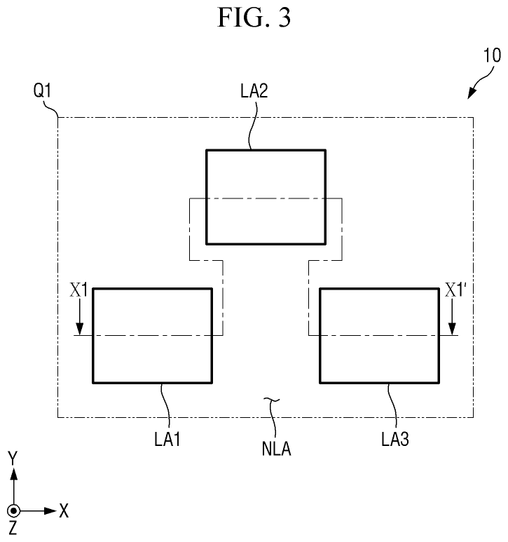

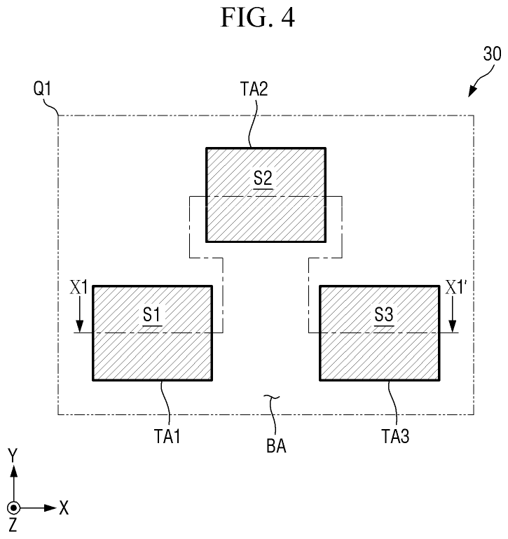

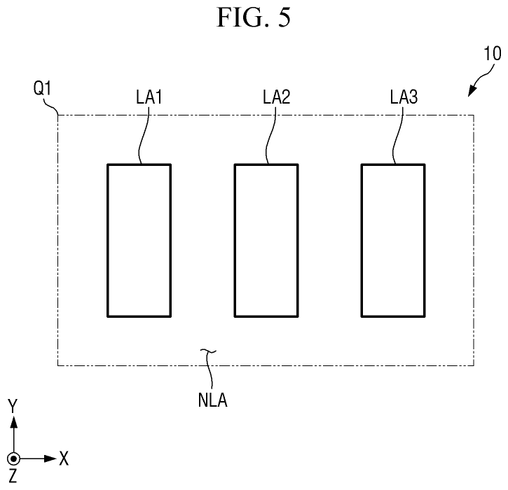

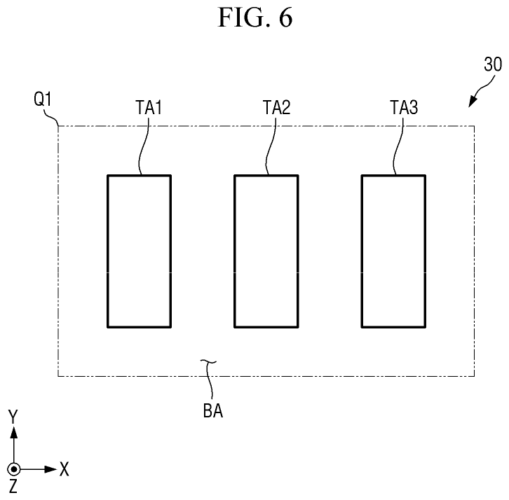

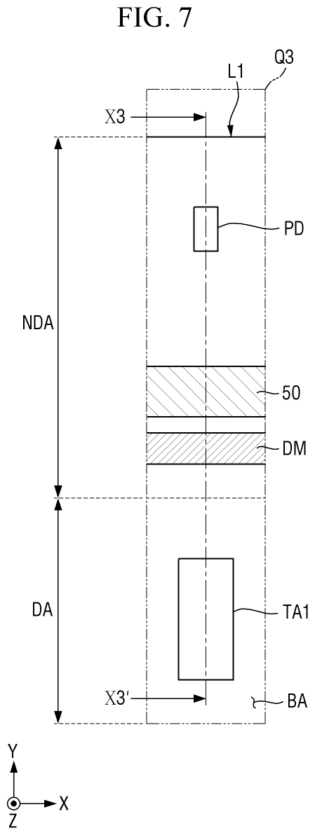

FIG. 2 is a plan view of a display device according to some embodiments of the present disclosure. FIG. 3 is an enlarged plan view of portion Q1 of FIG. 2, more specifically, a plan view of a display substrate included in the display device of FIG. 2. FIG. 4 is an enlarged plan view of portion Q1 of FIG. 2, more specifically, a plan view of a color conversion substrate included in the display device of FIG. 2. FIG. 5 is a plan view showing a modification of the example shown in FIG. 3 (e.g., another embodiment). FIG. 6 is a plan view showing a modification of the example shown in FIG. 4 (e.g., another embodiment). FIG. 7 is an enlarged plan view of portion Q3 of FIG. 2.

Referring to FIGS. 2 to 7 in conjunction with FIG. 1, according to some embodiments, the display device 1 may be formed in a rectangular shape in a plan view, as shown in FIG. 2. The display device 1 may include two sides extended in a first direction X, i.e., a first side L1 and a third side L3, and two sides extended in a second direction Y intersecting or crossing the first direction X, i.e., a second side L2 and a fourth side L4. Although the corners where the sides meet each other may form a right angle, the present disclosure is not limited thereto. In some embodiments, the length of the first side L1 and the third side L3 may be different from the length of the second side L2 and the fourth side L4. For example, the first side L1 and the third side L3 may be longer than the second side L2 and the fourth side L4. The shape of the display device 1 in the plan view is not limited to that shown in the drawings. The display device 1 may have a circular shape or other suitable shapes.

In some embodiments, the display device 1 may further include flexible circuit boards FPC and driver chip (e.g., driver chip integrated circuits) ICs.

As shown in FIG. 3, a plurality of emission areas LA1, LA2, and LA3 and a non-emission area NLA may be defined on the display substrate 10 in the display area DA.

In some embodiments, a first emission area LA1, a second emission area LA2, and a third emission area LA3 may be defined in the display area DA of the display substrate 10. In the emission areas LA1, LA2 and LA3, light generated in the light-emitting elements of the display substrate 10 exits (e.g., is emitted) out of the display substrate 10. In the non-emission area NLA, no light exit out of the display substrate 10. In some embodiments, the non-emission area NLA may be around (e.g., surround) the first emission area LA1, the second emission area LA2, and the third emission area LA3 inside the display area DA.

In some embodiments, the light exits (e.g., is emitted) out of the first emission area LA1, the second emission area LA2, and the third emission area LA3 may be light of a third color. In some embodiments, the light of the third color may be blue light and may have a peak wavelength in the range of approximately 440 to 480 nm. As used herein, the peak wavelength refers to the wavelength at which the intensity of the light is the greatest.

In some embodiments, the first emission area LA1, the second emission area LA2 and the third emission area LA3 may form a single group (e.g., a repeating unit), and a plurality of such groups may be defined in the display area DA.

As shown in FIG. 3, the first emission area LA1 and the third emission area LA3 may be adjacent to each other along the first direction X, while the second emission area LA2 may be located on one side of the first emission area LA1 and the third emission area LA3 along the second direction Y. It is, however, to be understood that the present disclosure is not limited thereto. The arrangement of the first emission area LA1, the second emission area LA2, and the third emission area LA3 may be altered in a variety of ways. For example, as shown in FIG. 5, the first emission area LA1, the second emission area LA2, and the third emission area LA3 may be located sequentially along the first direction X. In some embodiments, in the display area DA, the first emission area LA1, the second emission area LA2, and the third emission area LA3 may form a single group (e.g., a repeating unit) and may be repeatedly arranged along the first direction X and the second direction Y.

In the following description, an example will be described where the first emission area LA1, the second emission area LA2, and the third emission area LA3 are arranged as shown in FIG. 3.

As shown in FIG. 4, a plurality of light-transmitting areas TA1, TA2, and TA3 and a light-blocking area BA may be defined in the color conversion substrate 30 in the display area DA. In the light-transmitting areas TA1, TA2, and TA3, the light emitted from the display substrate 10 may transmit through the color conversion substrate 30 to be provided to the outside of the display device 1. In the light-blocking area BA, the light exiting (e.g., emitted) from the display substrate 10 cannot pass through it.

In some embodiments, a first light-transmitting area TA1, a second light-transmitting area TA2, and a third light-transmitting area TA3 may be defined on the color conversion substrate 30.

The first light-transmitting area TA1 may have the size equal to the size of the first emission area LA1 or may overlap the first emission area LA1. Similarly, the second light-transmitting area TA2 may have the size equal to the size of the second emission area LA2 or may overlap the second emission area LA2, and the third light-transmitting area TA3 may have the size equal to the size of the third emission area LA3 or may overlap the third emission area LA3.

When the first emission area LA1 and the third emission area LA3 are adjacent to each other in the first direction X while the second emission area LA2 is located on one side of the first emission area LA1 and the third emission area LA3 in the second direction Y as shown in FIG. 3, the first light-transmitting area TA1 and the third light-transmitting area TA3 may be adjacent to each other in the first direction X while the second light-transmitting area TA2 may be located on one side of the first light-transmitting area TA1 and the third light-transmitting area TA3 in the second direction Y.

In some embodiments, when the first emission area LA1, the second emission area LA2, and the third emission area LA3 are arranged sequentially along the first direction X as shown in FIG. 5, the first light-transmitting area TA1, the second light-transmitting area TA2, and the third light-transmitting area TA3 may also be arranged sequentially along the first direction X as shown in FIG. 6.

In some embodiments, each of the first light-transmitting area TA1, the second light-transmitting area TA2, and the third light-transmitting area TA3 may be of a quadrilateral shape in a plan view. For example, the quadrilateral shape may be a rectangular shape or a square. However, embodiments of the present disclosure are not limited thereto, and each of the first light-transmitting area TA1, the second light-transmitting area TA2, and the third light-transmitting area TA3 may have a circular shape, an elliptical shape, or other suitable polygonal shapes in a plan view.

In some embodiments, the light of the third color provided from the display substrate 10 may pass through the first light-transmitting area TA1, the second light-transmitting area TA2, and the third light-transmitting area TA3 to exit (e.g., to be emitted) out of the display device 1. In the following description, the light exiting out of the display device 1 through the first light-transmitting area TA1 is referred to as a first exiting light, the light exiting out of the display device 1 through the second light-transmitting area TA2 is referred to as a second exiting light, and the light exiting out of the display device 1 through the third light-transmitting area TA3 is referred to as a third exiting light. The first exiting light may be light of a first color, the second exiting light may be light of a second color different from the first color, and the third exiting light may be light of the third color. In some embodiments, the light of the third color may be blue light having a wavelength range from 380 to 500 nm and a peak wavelength in the range of approximately (about) 440 to (about) 480 nm, and the light of the first color may be red light having a wavelength range from 600 to 780 nm and a peak wavelength in the range of approximately (about) 610 to (about) 650 nm. In addition, the light of the second color may be green light having a wavelength range from 500 to 600 nm and a peak wavelength in the range of approximately (about) 510 to (a 550 nm.

The light-blocking area BA may be located in the display area DA around the first light-transmitting area TA1, the second light-transmitting area TA2, and the third light-transmitting area TA3. In some embodiments, the light-blocking BA may be around (e.g., surround) the first light-transmitting area TA1, the second light-transmitting area TA2, and the third light-transmitting area TA3. In addition, the light-blocking area BA may be located also in the non-display area NDA of the display device 1.

As shown in FIG. 4, the plurality of light-transmitting areas TA1, TA2, and TA3 and the light-blocking area BA may be defined in the color conversion substrate 30 in the display area DA. In the light-transmitting areas TA1, TA2, and TA3, the light emitted from the display substrate 10 may transmit through the color conversion substrate 30 to be provided to the outside of the display device 1. In the light-blocking area BA, the light exiting (emitted) from the display substrate 10 cannot pass through it.

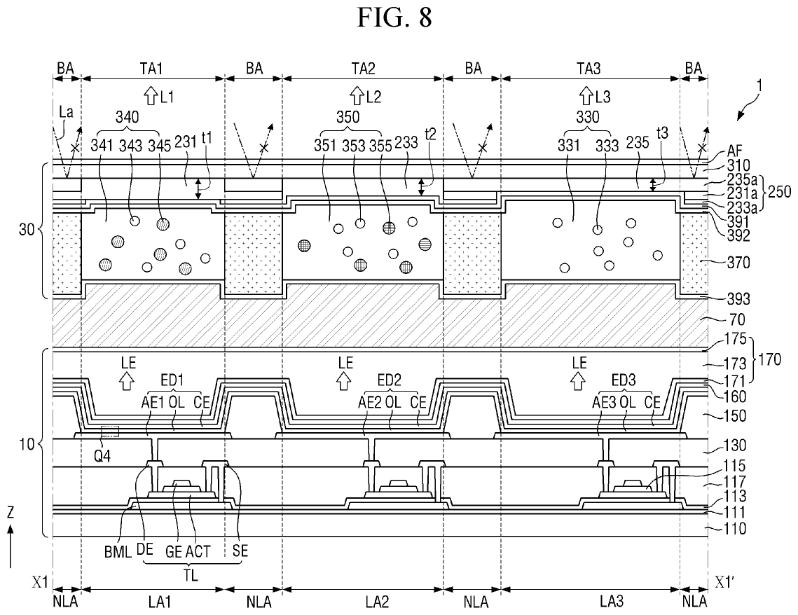

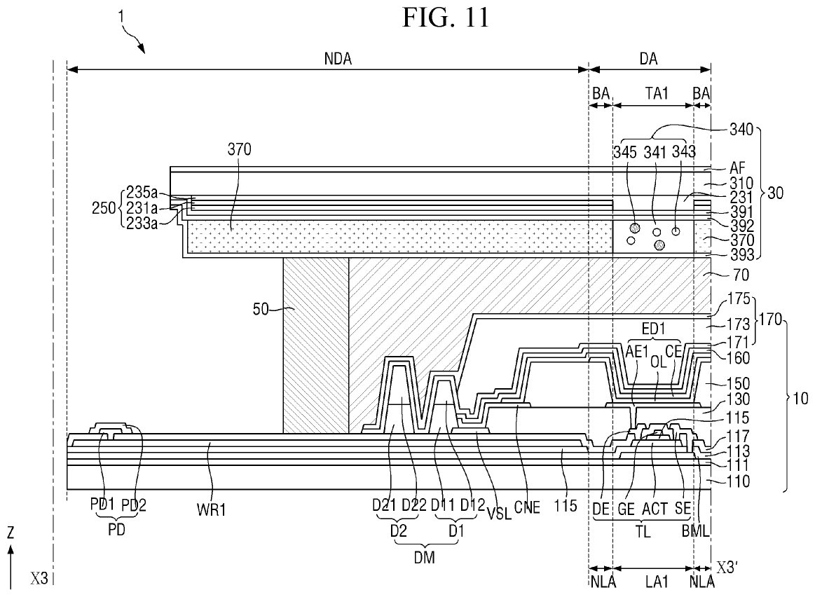

As shown in FIG. 4, the light-transmitting areas TA1, TA2, and TA2 of the color conversion substrate 30 may have the same areas as those of color filters 231, 233, and 235 shown in FIGS. 8 and 11. The color filters 231, 233, and 235 may be defined by the light-blocking area 250 (231a, 233a, and 235a) around (e.g., surrounding) each of the color filters 231, 233, and 235. The light-transmitting areas TA1, TA2, and TA3 of the color conversion substrate 30 of the display device 1 according to some embodiments may each have set or predetermined areas S1, S2, and S3. The set or predetermined areas S1, S2, and S3 of the light-transmitting areas TA1, TA2, and TA3 of the color conversion substrate 30 of the display device 1 according to some embodiments will be described in more detail later.

Referring back to FIG. 2, a dam member DM and a sealing member 50 may be located in the non-display area NDA of the display device 1.

The dam member DM can block or reduce the overflow of an organic material (or monomers) in the process of forming an encapsulation layer located in the display area DA, thereby preventing or substantially preventing the organic material in the encapsulation layer from extending (e.g., spreading) toward the edge of the display device 1.

In some embodiments, the dam member DM may be formed to be completely around (e.g., surround) the display area DA in a plan view.

The sealing member 50 may couple the display substrate 10 with the color conversion substrate 30 as described above.

The sealing member 50 may be located in the non-display area NDA on the outer side of the dam member DM and may be formed to be completely around (e.g., surround) the dam member DM and the display area DA when viewed from the top (e.g., in a plan view).

The non-display area NDA of the display device 1 may include a pad area PDA, and a plurality of connection pads PD may be located in the pad area PDA.

In some embodiments, the connection pads PD may be located adjacent to a longer side of the non-display area NDA and may be located adjacent to the first side L1 in the non-display area NDA, for example. The connection pads PD may be electrically connected to pixel circuits and/or the like located in the display area DA through connection lines and/or the like.

The display substrate 10 (see, e.g., FIG. 1) of the display device 1 may include the dam member DM and the connection pads PD.

Flexible circuit boards FPC may be connected to the connection pads PD. The flexible circuit boards FPC may electrically connect the display substrate 10 (see, e.g., FIG. 1) with circuit boards that provide signals, power, etc. for driving the display device 1.

Driver chips IC may be electrically connected to the circuit boards and/or the like to receive data and/or signals. In some embodiments, the driver chips IC may include a data driver chip and may receive a data control signal and image data from the circuit boards to generate and output a data voltage associated with image data.

In some embodiments, the driver chips IC may be mounted on the flexible circuit boards FPC, respectively. For example, the driver chips IC may be mounted on the flexible circuit boards FPC by a suitable (e.g., known) chip-on-film (COF) technique.

The data voltage supplied from the driver chips IC, the supply voltage supplied from the circuit boards, etc. may be transmitted to the pixel circuit of the display substrate 10 (see, e.g., FIG. 1) through the flexible circuit boards FPC and the connection pads PD.

Hereinafter, the structure of the display device 1 will be described in more detail.

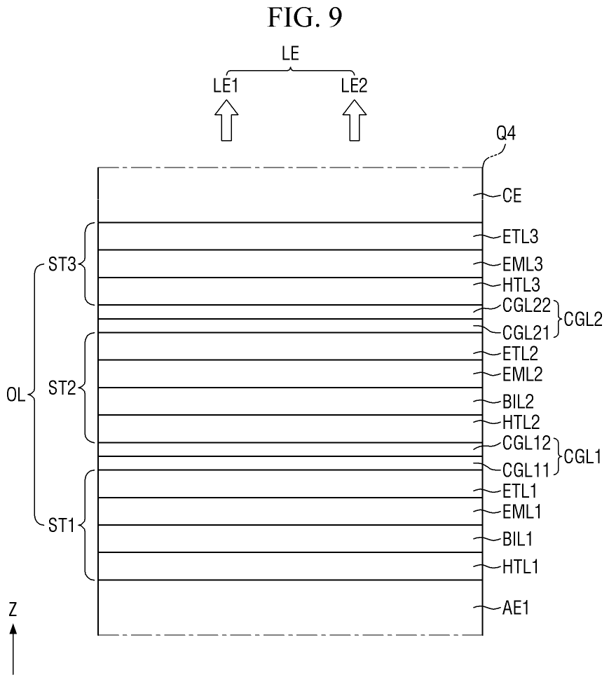

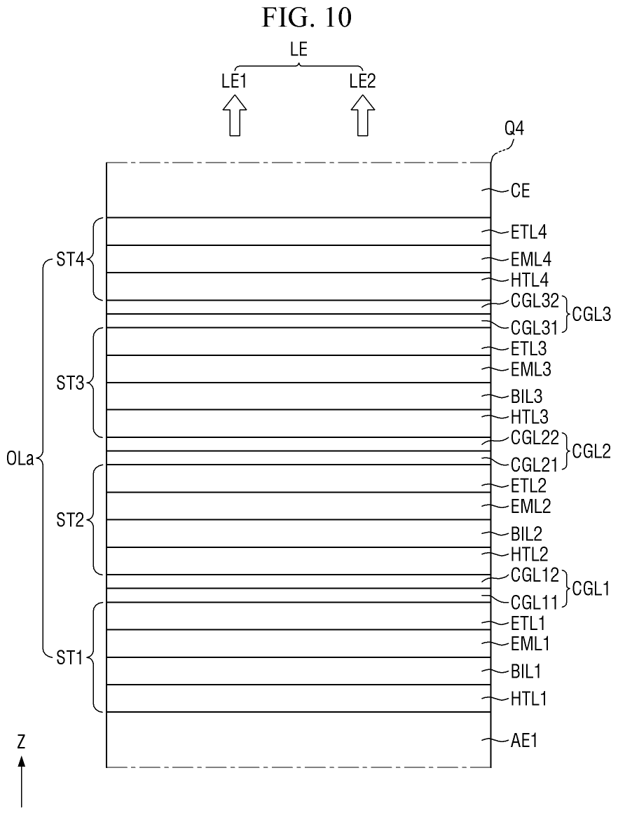

FIG. 8 is a cross-sectional view of the display device according to some embodiments of the present disclosure, taken along the line X1-X1′ of FIGS. 3 and 4. FIG. 9 is an enlarged cross-sectional view of portion Q4 of FIG. 8. FIG. 10 is a cross-sectional view showing a modification of the example of the structure shown in FIG. 9 (e.g., another embodiment). FIG. 11 is a cross-sectional view of the display device according to some embodiments of the present disclosure, taken along the line X3-X3′ of FIG. 7.

Referring to FIGS. 8 to 11 in conjunction with FIGS. 1 to 7, the display device 1 may include the display substrate 10 and the color conversion substrate 30 as described above, and may further include the filler 70 located between the display substrate 10 and the color conversion substrate 30.

Hereinafter, the display substrate 10 will be described in more detail.

A first base 110 may be made of a light-transmitting material. In some embodiments, the first base 110 may be a glass substrate and/or a plastic substrate. When the first base 110 is a plastic substrate, the first base 110 may have flexibility.

In some embodiments, the plurality of emission areas LA1, LA2, and LA3 and the non-emission area NLA may be defined on the first base 110 in the display area DA, which has been described above.

In some embodiments, the first side L1, the second side L2, the third side L3, and the fourth side L4 of the display device 1 may be identical to the four sides of the first base 110, respectively. That is, the first side L1, the second side L2, the third side L3, and the fourth side L4 of the display device 1 may be referred to as the first side L1, the second side L2, the third side L3, and the fourth side L4, respectively.

A buffer layer 111 may be further located on the first base 110. The buffer layer 111 may be located on the first base 110 in the display area DA and the non-display area NDA. The buffer layer 111 can block foreign substances and/or moisture from permeating through the first base 110. For example, the buffer layer 111 may include an inorganic material such as SiO₂, SiNx, and/or SiON, and may be made of a single layer or multiple layers.

A lower light-blocking layer BML may be located on the buffer layer 111. The lower light-blocking layer BML can block external light and/or light from the light-emitting element from entering a semiconductor layer ACT, which will be described in more detail later, thereby preventing or reducing leakage current from being generated by light in a thin-film transistor TL, which will be described in more detail later.

In some embodiments, the lower light-blocking layer BML may be made of a material that blocks light and has conductivity (e.g., is a conductor). For example, the lower light-blocking layer BML may include a single material of metals such as silver (Ag), nickel (Ni), gold (Au), platinum (Pt), aluminum (Al), copper (Cu), molybdenum (Mo), titanium (Ti), neodymium (Nd), or an alloy thereof. In some embodiments, the lower light-blocking layer BML may be made of a single layer or multi-layer structure. For example, when the lower light-blocking layer BML has a multi-layer structure, the lower light-blocking layer BML may have, but is not limited to, a stack structure of titanium (Ti)/copper (Cu)/indium tin oxide (ITO) or a stack structure of titanium (Ti)/copper (Cu)/aluminum oxide (A1203).

In some embodiments, the display substrate 10 may include a plurality of lower light-blocking layers BML. The number of the lower light-blocking layers BML may be equal to the number of the semiconductor layers ACT. Each of the lower light-blocking layers BML may overlap a respective one of the semiconductor layers ACT, respectively. In some embodiments, the width of the lower light-blocking layers BML may be greater than that of the semiconductor layers ACT.

In some embodiments, the lower light-blocking layer BML may be a part of a data line, a voltage supply line, a line that electrically connects a thin-film transistor with the thin-film transistor TL shown in the drawing, etc. In some embodiments, the lower light-blocking layer BML may be made of a material having a lower resistance than a second conductive layer or the source electrode SE and the drain electrode DE included in the second conductive layer.

A first insulating layer 113 may be located on the lower light-blocking layer BML. In some embodiments, the first insulating layer 113 may be located in the display area DA and the non-display area NDA. The first insulating layer 113 may cover the lower light-blocking layer BML. In some embodiments, the first insulating layer 113 may include an inorganic material such as SiO₂, SiNx, SiON, Al₂O₃, TiO₂, Ta₂O, HfO₂, ZrO₂, and/or the like.

The semiconductor layers ACT may be located on the first insulating layer 113. In some embodiments, the semiconductor layers ACT may be located in the first emission area LA1, the second emission area LA2, and the third emission area LA3 in the display area DA, respectively.

In some embodiments, the semiconductor layer ACT may include an oxide semiconductor. For example, the semiconductor layer ACT may be made of Zn oxide, In—Zn oxide, Ga—In—Zn oxide, etc., as Zn oxide-based material, and may be, for example, an IGZO (In—Ga—Zn—O) semiconductor containing a metal such as indium (In), and gallium (Ga) in ZnO. It is, however, to be understood that the present disclosure is not limited thereto. The semiconductor layers ACT may include amorphous silicon and/or polysilicon.

In some embodiments, the semiconductor layers ACT may be disposed to overlap the lower light-blocking layers BML, respectively, thereby suppressing generation of photocurrent in the semiconductor layers ACT.

A first conductive layer may be formed on the semiconductor layer ACT, and the first conductive layer may include the gate electrode GE and a first gate metal WR1. The gate electrode GE is located in the display area DA to overlap the respective semiconductor layer ACT. As shown in FIG. 11, the first gate metal WR1 may include a part of the line that electrically connects the connection pad PD (see, e.g., FIG. 2) with the elements located in the display area DA (see, e.g., FIG. 2), e.g., the thin-film transistor TL, the light-emitting element, etc.

The gate electrode GE and the first gate metal WR1 may include at least one of the materials including aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) and/or copper (Cu), and may be made of a single layer or multiple layers, taking into account adhesion to adjacent layers, surface flatness for a layer to be laminated thereon, workability, etc.

In the display area DA, a gate insulating layer 115 may be located between the semiconductor layer ACT and the first conductive layer or between the semiconductor layer ACT and the gate electrode GE. In some embodiments, the gate electrode GE and the gate insulating layer 115 may work (e.g., serve) as a mask for masking a channel region of the semiconductor layer ACT, and the width of the gate electrode GE and the width of the gate insulating layer 115 may be smaller than the width of the semiconductor layer ACT.

In some embodiments, the gate insulating layer 115 may not be formed as a single layer on the entire surface of the first base 110 but may be formed in a partially patterned shape. In some embodiments, the width of the patterned gate insulating layer 115 may be larger than the width of the gate electrode GE or the first conductive layer.

In some embodiments, the gate insulating layer 115 may include an inorganic material. For example, the gate insulating layer 115 may include the inorganic materials listed above as the materials of the first insulating layer 113.

In the non-display area NDA, the gate insulating layer 115 may be located between the first gate metal WR1 and the first insulating layer 113.

A second insulating layer 117 covering the semiconductor layer ACT and the gate electrode GE may be formed over the gate insulating layer 115. The second insulating layer 117 may be located in the display area DA and the non-display area NDA.

In some embodiments, the second insulating layer 117 may include an inorganic material. For example, the second insulating layer 117 may include the inorganic materials listed above as the materials of the first insulating layer 113. However, the present disclosure is not limited thereto, and the second insulating layer 117 may include an organic material.

The second conductive layer may be formed on the second insulating layer 117, and the second conductive layer may include the source electrode SE, the drain electrode DE, the voltage supply line VSL, and a first pad electrode PD1 of the connection pads PD.

The source electrode SE and the drain electrode DE may be located in the display area DA and may be spaced apart from each other. The drain electrode DE and the source electrode SE may each pass (e.g., penetrate) through the second insulating layer 117 and be connected to the semiconductor layer ACT.

In some embodiments, the source electrode SE may pass (e.g., penetrate) through the first insulating layer 113 and the second insulating layer 117 and be connected to the lower light-blocking layer BML. When the lower light-blocking layer BML is a part of a line that transmits a signal and/or a voltage, the source electrode SE may be connected to and electrically coupled with the lower light-blocking layer BML and may receive the voltage applied to the line. In some embodiments, when the lower light-blocking layer BML is a floating pattern rather than a separate line, a voltage applied to the source electrode SE and/or the like may be transmitted to the lower light-blocking layer BML.

In some embodiments, unlike the example shown in FIG. 8, the drain electrode DE may pass (e.g., penetrate) through the first insulating layer 113 and the second insulating layer 117 and may be connected to the lower light-blocking layer BML. When the lower light-blocking layer BML is not a line receiving a separate signal, a voltage applied to the drain electrode DE and/or the like may be transmitted to the lower light-blocking layer BML.

The semiconductor layer ACT, the gate electrode GE, the source electrode SE and the drain electrode DE may form the thin-film transistor TL which is a switching element. In some embodiments, the thin-film transistor TL may be located in each of the first emission area LA1, the second emission area LA2 and the third emission area LA3. In some embodiments, a part of the thin-film transistor TL may be located in the non-emission area NLA.

The voltage supply line VSL may be located in the non-display area NDA. A supply voltage applied to a cathode electrode CE, for example, a voltage ELVSS may be supplied to the voltage supply line VSL.

The first pad electrode PD1 of the connection pads PD may be located in the pad area PDA (see, e.g., FIG. 2) of the non-display area NDA. In some embodiments, the first pad electrode PD1 may pass (e.g., penetrate) through the second insulating layer 117 and may (e.g., so as to) be electrically connected to the first gate metal WR1.

The source electrode SE, the drain electrode DE, the voltage supply line VSL, and the first pad electrode PD1 of the connection pad PD may each include aluminum (Al), copper (Cu), titanium (Ti), etc., and may be made of multiple layers or a single layer. In some embodiments of the present disclosure, the source electrode SE, the drain electrode DE, the voltage supply line VSL and the first pad electrode PD1 of the connection pad PD may each be made of a multilayer structure of Ti/Al/Ti.

A third insulating layer 130 may be located on the second insulating layer 117. The third insulating layer 130 may cover the thin-film transistor TL in the display area DA and may expose a part of the voltage supply line VSL in the non-display area NDA.

In some embodiments, the third insulating layer 130 may be a planarization layer. In some embodiments, the third insulating layer 130 may be made of an organic material. For example, the third insulating layer 130 may include an acrylic resin, an epoxy resin, an imide resin, an ester resin, etc. In some embodiments, the third insulating layer 130 may include a photosensitive organic material.

A first anode electrode AE1, a second anode electrode AE2 and a third anode electrode AE3 may be located on the third insulating layer 130 in the display area DA. In addition, a connection electrode CNE and a second pad electrode PD2 of the connection pad PD may be located on the third insulating layer 130 in the non-display area NDA.

The first anode electrode AE1 may overlap the first emission area LA1 and may be at least partially extended to the non-emission area NLA. The second anode electrode AE2 may overlap the second emission area LA2 and may be at least partially extended to the non-emission area NLA, and the third anode electrode AE3 may overlap the third emission area LA3 and may be at least partially extended to the non-emission area NLA. The first anode electrode AE1 may pass (e.g., penetrate) through the third insulating layer 130 and may be connected to the drain electrode DE of the thin-film transistor TL associated with the first anode electrode AE1. The second anode electrode AE2 may pass (e.g., penetrate) through the third insulating layer 130 and may be connected to the drain electrode DE of the thin-film transistor TL associated with the second anode electrode AE2. The third anode electrode AE3 may pass (e.g., penetrate) through the third insulating layer 130 and may be connected to the drain electrode DE of the thin-film transistor TL associated with the third anode electrode AE3.

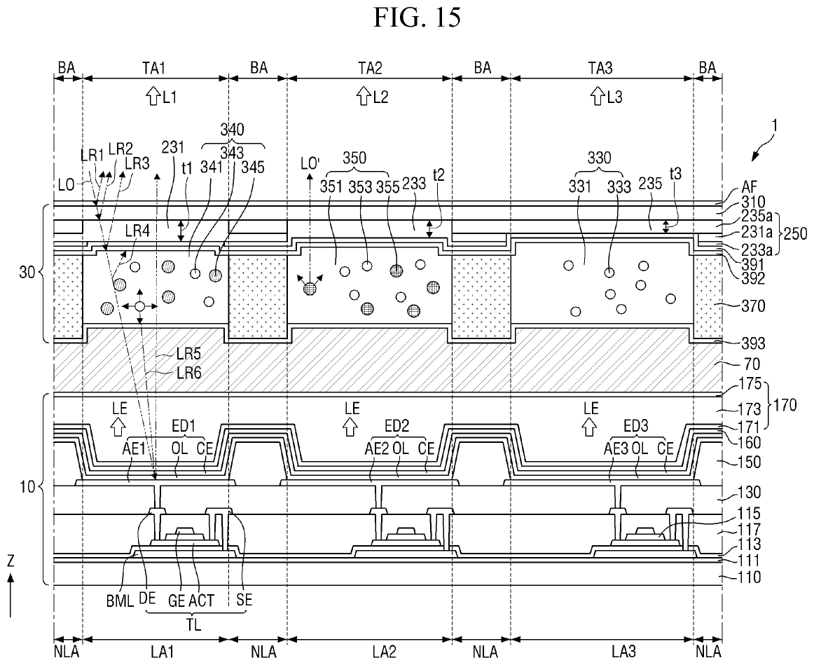

In some embodiments, the first anode electrode AE1, the second anode electrode AE2, and the third anode electrode AE3 may be reflective electrodes. In such case, the first anode electrode AE1, the second anode electrode AE2, and the third anode electrode AE3 may be one or more metal layers containing a metal such as Ag, Mg, Al, Pt, Pd, Au, Ni, Nd, Ir, and/or Cr. In alternative embodiments, the first anode electrode AE1, the second anode electrode AE2, and the third anode electrode AE3 may further include a metal oxide layer stacked on the metal layer. According to example embodiments, the first anode electrode AE1, the second anode electrode AE2, and the third anode electrode AE3 may have a multi-layer structure, e.g., a two-layer structure of ITO/Ag, Ag/ITO, ITO/Mg, or ITO/MgF, or a three-layer structure of ITO/Ag/ITO. When the first anode electrode AE1, the second anode electrode AE2, and the third anode electrode AE3 include reflective electrodes, a part of external light LO (see, e.g., FIG. 15) incident from the outside of the display device 1 may be reflected from the first anode electrode AE1, the second anode electrode AE2, and the third anode electrode AE3.

The connection electrode CNE may be electrically connected to the voltage supply line VSL in the non-display area NDA and may be in direct contact with the voltage supply line VSL.

The second pad electrode PD2 may be located on the first pad electrode PD1 in the non-display area NDA. The second pad electrode PD2 may be in direct contact with and electrically connected to the first pad electrode PD1.

In some embodiments, the connection electrode CNE and the second pad electrode PD2 may be made of the same material as the first anode electrode AE1, the second anode electrode AE2, and the third anode electrode AE3, and may be formed together with the first anode electrode AE1, the second anode electrode AE2, and the third anode electrode AE3 via the same fabricating process.

A pixel-defining layer 150 may be located on the first anode electrode AE1, the second anode electrode AE2, and the third anode electrode AE3. The pixel-defining layer 150 may include an opening for exposing the first anode electrode AE1, an opening for exposing the second anode electrode AE2, and an opening for exposing the third anode electrode AE3 and may define the first light-emitting region LA1, the second light-emitting region LA2, the third light-emitting region LA3, and the non-light-emitting region NLA. That is, an exposed part of the first anode electrode AE1 which is not covered by the pixel-defining layer 150 may be the first light-emitting area LA1. Similarly, an exposed part of the second anode electrode AE2 which is not covered by the pixel-defining layer 150 may be the second light-emitting area LA2. An exposed part of the third anode electrode AE3 which is not covered by the pixel-defining layer 150 may be the third light-emitting area LA3. The pixel-defining layer 150 may be located in the non-emission area NLA.

In some embodiments, the pixel-defining layer 150 may include an organic insulating material such as polyacrylate resin, epoxy resin, phenolic resin, polyamide resin, polyimide resin, unsaturated polyester resin, poly phenylene ether resin, poly phenylene sulfide resin, and/or benzocyclobutene (BCB).

In some embodiments, the pixel-defining layer 150 may overlap a light-blocking pattern 250 to be described in more detail later. In addition, according to some embodiments, the pixel-defining layer 150 may overlap a bank pattern 370 to be described in more detail later.

As shown in FIGS. 8 and 11, an emissive layer OL may be located on the first anode electrode AE1, the second anode electrode AE2, and the third anode electrode AE3.

In some embodiments, the emissive layer OL may have the shape of a continuous film formed across the plurality of emission areas LA1, LA2 and LA3 and the non-emission area NLA. Although the emissive layer OL is located only in the display area DA in the drawings, embodiments according to the present disclosure are not limited thereto. In some alternative embodiments, a part of the emissive layer OL may be further located in the non-display area NDA. The emissive layer OL will be described in more detail later.

The cathode electrode CE may be located on the emissive layer OL. A part of the cathode electrode CE may be further located in the non-display area NDA. The cathode electrode CE may be electrically connected to the connection electrode CNE in the non-display area NDA and may be in contact with the connection electrode CNE. The voltage supply line VSL may be located in the non-display area NDA. A supply voltage applied to a cathode electrode CE, for example, a voltage ELVSS may be supplied to the voltage supply line VSL.

In some embodiments, the cathode electrode may be semi-transmissive or transmissive. When the cathode electrode CE is semi-transmissive, it may include Ag, Mg, Cu, Al, Pt, Pd, Au, Ni, Nd, Ir, Cr, Li, Ca, LiF/Ca, LiF/Al, Mo, Ti, or a compound and/or a mixture thereof, e.g., a mixture of Ag and Mg. Further, when the thickness of the cathode electrode CE ranges from several tens to several hundred angstroms, the cathode electrode CE may be semi-transmissive.

When the cathode electrode CE is transmissive, the cathode electrode CE may include a transparent conductive oxide (TCO). For example, the cathode electrode CE may be formed of tungsten oxide (WxOx), titanium oxide (TiO₂), indium tin oxide (ITO), indium zinc oxide (IZO), zinc oxide (ZnO), indium tin zinc oxide, MgO (magnesium oxide), etc.

In some embodiments, the cathode electrode CE may completely cover the emissive layer OL. In some embodiments, as shown in FIG. 11, the end of the cathode electrode CE may be located more to the outside (e.g., toward the edge of the first base 110) than the end of the emissive layer OL, and the end of the emissive layer OL may be completely covered by the cathode electrode CE.

The first anode electrode AE1, the emissive layer OL, and the cathode electrode CE may form a first light-emitting element ED1, the second anode electrode AE2, the emissive layer OL, and the cathode electrode CE may form a second light-emitting element ED2, and the third anode electrode AE3, the emissive layer OL, and the cathode electrode CE may form a third light-emitting element ED3. Each of the first light-emitting element ED1, the second light-emitting element ED2 and the third light-emitting element ED3 may emit exiting light LE.

As shown in FIG. 9, the exiting light LE finally emitted from the emissive layer OL may be a mixed light of a first component LE1 and a second component LE2. Each of the first component LE1 and the second component LE2 of the exiting light LE may have a peak wavelength that is equal to or greater than 440 nm and less than 480 nm. That is, the exiting light LE may be blue light.

As shown in FIG. 9, according to some embodiments, the emissive layer OL may have a structure in which a plurality of emissive layers overlap one another, e.g., a tandem structure. For example, the emissive layer OL may include a first stack ST1 including the first emissive layer EML1, a second stack ST2 located on the first stack ST1 and including the second emissive layer EML2, a third stack ST3 located on the second stack ST2 and including the third emissive layer EML3, a first charge generation layer CGL1 located between the first stack ST1 and the second stack ST2, and a second charge generation layer CGL2 located between the second stack ST2 and the third stack ST3. The first stack ST1, the second stack ST2, and the third stack ST3 may overlap one another (e.g., in the thickness or Z direction or in a plan view).

The first emission layer EML1, the second emission layer EML2, and the third emission layer EML3 may overlap one another.

In some embodiments, the first emission layer EML1, the second emission layer EML2, and the third emission layer EML3 may all emit light of the first color, e.g., blue light. For example, each of the first emission layer EML1, the second emission layer EML2, and the third emission layer EML3 may be a blue light emission layer and may include an organic material.

In some embodiments, at least one of the first emission layer EML1, the second emission layer EML2, or the third emission layer EML3 may emit a first blue light having a first peak wavelength, and at least another one of the first emission layer EML1, the second emission layer EML2, or the third emission layer EML3 may emit a second blue light having a second peak wavelength different from the first peak wavelength. For example, one selected from the first emission layer EML1, the second emission layer EML2, and the third emission layer EML3 may emit the first blue light having the first peak wavelength, and the other two selected from the first emission layer EML1, the second emission layer EML2, and the third emission layer EML3 may each emit the second blue light having the second peak wavelength. For example, the exiting light LE finally emitted from the emissive layer OL may be mixed light of the first component LE1 and the second component LE2, and the first component LE1 may be the first blue light having the first peak wavelength, and the second component LE2 may be the second blue light having the second peak wavelength.

In some embodiments, the range of one selected from the first peak wavelength and the second peak wavelength may be equal to or greater than 440 nm and less than 460 nm, and the range of the other one selected from the first peak wavelength and the second peak wavelength may be equal to or greater than 460 nm and less than 480 nm. It is, however, to be understood that the ranges of the first peak wavelength and the range of the second peak wavelength are not limited thereto. For example, the range of the first peak wavelength and the range of the second peak wavelength may both (e.g., simultaneously) include 460 nm. In some embodiments, one selected from the first blue light and the second blue light may be light of deep blue color, while the other one selected from the first blue light and the second blue light may be light of sky blue color.

In some embodiments, the exiting light LE emitted from the emissive layer OL is blue light and may include a long-wavelength component and a short-wavelength component. Therefore, the emissive layer OL may finally emit blue light having an emission peak broadly distributed as the exiting light LE. In this manner, the color visibility may be improved at side viewing angles compared to alternative light-emitting elements that emit blue light having a sharp (e.g., narrower) emission peak.

In some embodiments, each of the first emission layer EML1, the second emission layer EML2, and the third emission layer EML3 may include a host and a dopant. The material of the host is not particularly limited herein as long as it is typically or suitably utilized and may include Alq3(tris(8-hydroxyquinolino)aluminum), CBP(4,4′-bis(N-carbazolyl)-1,1′-biphenyl), PVK(poly(n-vinylcabazole)), ADN(9,10-di(naphthalene-2-yl)anthracene), TCTA(4,4′,4″-Tris(carbazol-9-yl)-triphenylamine), TPBi(1,3,5-tris(N-phenylbenzimidazole-2-yl)benzene), TBADN(3-tert-butyl-9,10-di(naphth-2-yl)anthracene), DSA(distyrylarylene), CDBP(4,4′-bis(9-carbazolyl)-2,2″-dimethyl-biphenyl), MADN(2-Methyl-9,10-bis(naphthalen-2-yl)anthracene), etc.

Each of the first emission layer EML1, the second emission layer EML2, and the third emission layer EML3 that emits blue light may include a fluorescent material including one selected from the group consisting of: spiro-DPVBi, spiro-6P, DSB (distyryl-benzene), DSA (distyryl-arylene), PFO (polyfluorene) polymer, and PPV (poly(p-phenylene vinylene)) polymer. As another example, each of the first emission layer EML1, the second emission layer EML2, and the third emission layer EML3 may include a phosphorescent material including an organometallic complex such as (4,6-F2ppy)2Irpic.

As described above, at least one selected from the first emission layer EML1, the second emission layer EML2, and the third emission layer EML3 may emit blue light in a different wavelength range from that of at least another one selected from the first emission layer EML1, the second emission layer EML2, and the third emission layer EML3. In order to emit blue light in different wavelength ranges, the first emission layer EML1, the second emission layer EML2 and the third emission layer EML3 may include the same material and the resonance distance may be adjusted. In some embodiments, in order to emit blue light in different wavelength ranges, at least one or more selected from the first emission layer EML1, the second emission layer EML2, and the third emission layer EML3 may include a different material from one another.

It is, however, to be understood that the present disclosure is not limited thereto. The blue light emitted by each of the first emission layer EML1, the second emission layer EML2, and the third emission layer EML3 may all have a peak wavelength of 440 nm to 480 nm, and may be made of the same material.

Alternatively, in other alternative embodiments, a first one selected from the first emission layer EML1, the second emission layer EML2, and the third emission layer EML3 may emit the first blue light having the first peak wavelength, a second one selected from the first emission layer EML1, the second emission layer EML2, and the third emission layer EML3 may emit the second blue light having the second peak wavelength different from the first peak wavelength, and a third one selected from the first emission layer EML1, the second emission layer EML2, and the third emission layer EML3 may emit the third blue light having a third peak wavelength different from the first peak wavelength and the second peak wavelength. In other alternative embodiments, the range of a first one selected from the first peak wavelength, the second peak wavelength, and the third peak wavelength may be equal to or greater than 440 nm and less than 460 nm. The range of a second one selected from the first peak wavelength, the second peak wavelength, and the third peak wavelength may be equal to or greater than 460 nm and less than 470 nm. The range of the third one selected from the first peak wavelength, the second peak wavelength, and the third peak wavelength may be equal to or greater than 470 nm and less than 480 nm.

According to other alternative embodiments, the exiting light LE emitted from the emissive layer OL is blue light and may include a long-wavelength component, a medium-wavelength component, and a short-wavelength component. Therefore, the emissive layer OL may finally emit blue light having an emission peak broadly distributed as the exiting light LE, and the color visibility at the side viewing angles can be improved.

In the display devices according to the embodiments described above, in contrast to light-emitting elements that do not employ the tandem structure, because of the structure in which a number of light-emitting elements may be stacked on one another, the luminous efficiency may be relatively increased and the lifetime (e.g., lifespan) of the display device may also be relatively improved.

Alternatively, according to some alternative embodiments, at least one of the first emission layer EML1, the second emission layer EML2, or the third emission layer EML3 may emit light of the third color, e.g., blue light, and at least another one of the first emission layer EML1, the second emission layer EML2, or the third emission layer EML3 may emit light of the second color, e.g., green light. In some other embodiments, the range of peak wavelength of blue light emitted by at least one of the first emission layer EML1, the second emission layer EML2, or the third emission layer EML3 may be from 440 nm to 480 nm, or from 460 nm to 480 nm. The green light emitted by at least another one of the first emission layer EML1, the second emission layer EML2, or the third emission layer EML3 may have a peak wavelength in the range of 510 nm to 550 nm.

For example, one selected from the first emission layer EML1, the second emission layer EML2, and the third emission layer EML3 may be a green light emission layer emitting green light, while the other two selected from the first emission layer EML1, the second emission layer EML2, and the third emission layer EML3 may be blue light emission layers emitting blue light. When the other two selected from the first emission layer EML1, the second emission layer EML2, and the third emission layer EML3 are blue light emission layers, the range of the peak wavelength of the blue light emitted by the two blue light emission layers may be equal to each other or different from each other.

In some embodiments, the exiting light LE emitted from the emissive layer OL may be a mixed light of the first component LE1 which is blue light and the second component LE2 which is green light. For example, when the first component LE1 is deep blue light and the second component LE2 is green light, the exiting light LE may be light of a sky blue color. Similarly to the above-described embodiments, the exiting light LE emitted from the emissive layer OL is a mixed light of blue light and green light, and includes a long-wavelength component and a short-wavelength component. Therefore, the emissive layer OL may finally emit blue light having an emission peak broadly distributed as the exiting light LE, and the color visibility at the side viewing angles can be improved. In addition, because the second component LE2 of the exiting light LE is green light, green light component of the light provided from the display device 1 to the outside can be supplemented, and accordingly the color reproducibility of the display device 1 can be improved.

In some embodiments, the green light emission layer selected from the first emission layer EML1, the second emission layer EML2 and the third emission layer EML3 may include a host and a dopant. The material of the host included in the green light emission layer is not particularly limited herein as long as it is typically utilized and may include Alq3 (tris(8-hydroxyquinolino)aluminum), CBP (4,4′-bis(N-carbazolyI)-1,1′-biphenyl), PVK (poly(n-vinylcabazole)), ADN (9,10-di(naphthalene-2-yl)anthracene), TCTA (4,4′,4″-Tris(carbazol-9-yl)-triphenylamine), TPBi (1,3,5-tris(N-phenylbenzimidazole-2-yl)benzene), TBADN (3-tert-butyl-9,10-di(naphth-2-yl)anthracene), DSA (distyrylarylene), CDBP (4,4′-bis(9-carbazolyl)-2,2″-dimethyl-biphenyl), MADN (2-Methyl-9,10-bis(naphthalen-2-yl)anthracene), etc.

The dopant included in the green light emission layer may include, for example, a fluorescent material such as Alq3 (tris-(8-hydroyquinolato) aluminum(III)), and/or a phosphorescent material such as Ir(ppy)3 (fac tris(2-phenylpyridine)iridium), Ir(ppy)2(acac) (Bis(2-phenylpyridine)(acetylacetonate)iridium(III)) and/or Ir(mpyp)3 (2-phenyl-4-methyl-pyridine iridium).

The first charge generation layer CGL1 may be located between the first stack ST1 and the second stack ST2. The first charge generation layer CGL1 may serve to inject charges into each of the emission layers. The first charge generation layer CGL1 may control charge balance between the first stack ST1 and the second stack ST2. The first charge generation layer CGL1 may include an n-type charge (e.g., N-charge) generation layer CGL11 and a p-type charge (e.g., P-charge) generation layer CGL12. The p-type charge generation layer CGL12 may be located on the n-type charge generation layer CGL11 and may be between the n-type charge generation layer CGL11 and the second stack ST2.

The first charge generation layer CGL1 may have a junction structure in which the n-type charge generation layer CGL11 and the p-type charge generation layer CGL12 are bonded with each other. The n-type charge generation layer CGL11 is located closer to the anode electrodes AE1, AE2, and AE3 than to the cathode electrode CE. The p-type charge generation layer CGL12 is located closer to the cathode electrode CE than to the anode electrodes AE1, AE2, and AE3. The n-type charge generation layer CGL11 supplies electrons to the first emission layer EML1 adjacent to the anode electrodes AE1, AE2, and AE3, and the p-type charge generation layer CGL12 supplies holes to the second emission layer EML2 included in the second stack ST2. By locating the first charge generation layer CGL1 between the first stack ST1 and the second stack ST2, charges are supplied to each of the emission layers to increase the luminous efficiency and to lower the supply voltage.

The first stack ST1 may be located on the first anode electrode AE1, the second anode electrode AE2, and the third anode electrode AE3, and may further include a first hole transport layer HTL1, a first electron block layer BILI, and a first electron transport layer ETL1.

The first hole transport layer HTL1 may be located on the first anode electrode AE1, the second anode electrode AE2, and the third anode electrode AE3. The first hole transport layer HTL1 may facilitate the transport of holes and may include a hole transport material. The hole transport material may include, but is not limited to, one or more carbazole derivatives such as N-phenylcarbazole and/or polyvinylcarbazole, fluorene derivatives, triphenylamine derivatives such as TPD (N,N′-bis(3-methylphenyl)-N,N′-diphenyl-[1,1-biphenyl]-4,4′-diamine) and/or TCTA (4,4′,4″-tris(N-carbazolyl)triphenylamine), NPB (N,N′-di(1-naphthyl)-N,N′-diphenylbenzidine), TAPC (4,4′-Cyclohexylidene bis[N,N-bis(4-methylphenyl)benzenamine]), etc.

The first electron block layer BIL1 may be located on the first hole transport layer HTL1, and may be located between the first hole transport layer HTL1 and the first emission layer EML1. The first electron block layer BIL1 may include the hole transport material and a metal and/or a metal compound to prevent or substantially prevent the electrons generated in the first emission layer EML1 from flowing into the first hole transport layer HTL1. In some embodiments, the first hole transport layer HTL1 and the first electron block layer BIL1 described above may each be a single layer where the materials are mixed.

The first electron transport layer ETL1 may be located on the first emission layer EML1, and may be located between the first charge generation layer CGL1 and the first emission layer EML1. In some embodiments, the first electron transport layer ETL1 may include an electron transparent material such as Alq3 (Tris(8-hydroxyquinolinato)aluminum), TPBi (1,3,5-Tri(1-phenyl-1H-benzo[d]imidazol-2-yl)phenyl), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq (Bis(2-methyl-8-quinolinolato-N1,08)-(1,1′-Biphenyl-4-olato)aluminum), Bebq2 (berylliumbis(benzoquinolin-10-olate), ADN (9,10-di(naphthalene-2-yl)anthracene) or a mixture thereof. It is, however, to be noted that the type of the electron transport material is not particularly limited to the examples listed above. The second stack ST2 may be located on the first charge generation layer CGL1 and may further include a second hole transport layer HTL2, a second electron block layer BIL2, and a second electron transport layer ETL2.

The second hole transport layer HTL2 may be located on the first charge generation layer CGL1. The second hole transport layer HTL2 may be made of the same material as the first hole transport layer HTL1 or may include one or more materials selected from the materials listed above as materials included in the first hole transport layer HTL1. The second hole transport layer HTL2 may be made of a single layer or multiple layers.

The second electron block layer BIL2 may be located on the second hole transport layer HTL2 and may be located between the second hole transport layer HTL2 and the second emission layer EML2. The second electron block layer BIL2 may be made of the same material and the same structure as the first electron block layer BIL1 or may include one or more materials selected from the materials listed above as the materials included in the first electron block layer BIL1.

The second electron transport layer ETL2 may be located on the second emission layer EML2, and may be located between the second charge generation layer CGL2 and the second emission layer EML2. The second electron transport layer ETL2 may be made of the same material and the same structure as the first electron transport layer ETL1 or may include one or more materials selected from the materials listed above as the materials included in the first electron transport layer ETL1. The second electron transport layer ETL2 may be made of a single layer or multiple layers.

The second charge generation layer CGL2 may be located on the second stack ST2 and may be located between the second stack ST2 and the third stack ST3.

The second charge generation layer CGL2 may have the same structure as the first charge generation layer CGL1 described above. For example, the second charge generation layer CGL2 may include an n-type charge generation layer CGL21 located closer to the second stack ST2 and a p-type charge generation layer CGL22 located closer to the cathode electrode CE. The p-type charge generation layer CGL22 may be located on the n-type charge generation layer CGL21.

The second charge generation layer CGL2 may have a junction structure in which the n-type charge generation layer CGL21 and the p-type charge generation layer CGL22 are bonded with each other. The first charge generation layer CGL1 and the second charge generation layer CGL2 may be made of different materials or may be made of the same material.

The second stack ST2 may be located on the second charge generation layer CGL2 and may further include a third hole transport layer HTL3 and a third electron transport layer ETL3.

The third hole transport layer HTL3 may be located on the second charge generation layer CGL2. The third hole transport layer HTL3 may be made of the same material as the first hole transport layer HTL1 or may include one or more materials selected from the materials listed above as the materials included in the first hole transport layer HTL1. The third hole transport layer HTL3 may be made of a single layer or multiple layers. When the third hole transport layer HTL3 is made of multiple layers, the layers may include different materials.

The third electron transport layer ETL3 may be located on the third emission layer EML3, and may be located between the cathode electrode CE and the third emission layer EML3. The third electron transport layer ETL3 may be made of the same material and the same structure as the first electron transport layer ETL1 or may include one or more materials selected from the materials listed above as the materials included in the first electron transport layer ETL1. The third electron transport layer ETL3 may be made of a single layer or multiple layers. When the third electron transport layer ETL3 is made of multiple layers, the layers may include different materials.

In some embodiments, a hole injection layer may be further located between the first stack ST1 and the first anode electrode AE1, the second anode electrode AE2, and the third anode electrode AE3, between the second stack ST2 and the first charge generation layer CGL1, and/or between the third stack ST3 and the second charge generation layer CGL2. The hole injection layer may facilitate injection of holes into the first emission layer EML1, the second emission layer EML2 and the third emission layer EML3. In some embodiments, the hole injection layer may be made of, but the present disclosure is not limited to, at least one selected from the group consisting of: CuPc (copper phthalocyanine), PEDOT (poly(3,4)-ethylenedioxythiophene), PANI (polyaniline), and NPD (N,N-dinaphthyl-N,N′-diphenyl benzidine). In some embodiments, the hole injection layer may be located between the first stack ST1 and the first anode electrode AE1, the second anode electrode AE2, and the third anode electrode AE3, between the second stack ST2 and the first charge generation layer CGL1, and between the third stack ST3 and the second charge generation layer CGL2.

In some embodiments, an electron injection layer may be further located between the third electron transport layer ETL3 and the cathode electrode CE, between the second charge generation layer CGL2 and the second stack ST2, and/or between the first charge generation layer CGL1 and the first stack ST1. The electron injection layer facilitates the injection of electrons and may be made of, but the present disclosure is not limited to, Alq3(tris(8-hydroxyquinolino)aluminum), PBD, TAZ, spiro-PBD, BAlq, and/or SAlq. In addition, the electron injection layer may be a metal halide compound and may be, but is not limited to, at least one selected from the group consisting of: MgF2, LiF, NaF, KF, RbF, CsF, FrF, LiI, NaI, KI, RbI, CsI, FrI and CaF2. In addition, the electron injection layer may include a lanthanide-based material such as Yb, Sm, and/or Eu. In some embodiments, the electron injection layer may include a metal halide material as well as a lanthanide material such as RbI:Yb and/or KI:Yb. When the electron injection layer includes both (e.g., simultaneously) a metal halide material and a lanthanide material, the electron injection layer may be formed by co-deposition of the metal halide material and the lanthanide material. In some embodiments, the electron injection layer may be located between the third electron transport layer ETL3 and the cathode electrode CE, between the second charge generation layer CGL2 and the second stack ST2, and between the first charge generation layer CGL1 and the first stack ST1.

In addition to the above-described structure, the structure of the emissive layer OL may be suitably altered. For example, the emissive layer OL may be modified as an emissive layer OLa shown in FIG. 10. Unlike the structure shown in FIG. 9, the emissive layer OLa shown in FIG. 10 may further include a fourth stack ST4 located on the third stack ST3, and may further include a third charge generation layer CGL3 located between the third stack ST3 and the fourth stack ST4.

The fourth stack ST4 may include a fourth emission layer EML4 and may further include a fourth hole transport layer HTL4, a third electron block layer BIL3, and a fourth electron transport layer ETL4.

The first emission layer EML1, the second emission layer EML2, the third emission layer EML3, and the fourth emission layer EML4 that are included in the emissive layer OLa may all emit light of the third color, e.g., blue light. At least one of the first emission layer EML1, the second emission layer EML2, the third emission layer EML3, or the fourth emission layer EML4 may emit blue light in a different wavelength range from that of at least another one selected from the first emission layer EML1, the second emission layer EML2, the third emission layer EML3, and the fourth emission layer EML4.

In some embodiments, at least one of the first emission layer EML1, the second emission layer EML2, the third emission layer EML3, or the fourth emission layer EML4 may emit green light, and at least another one selected from the first emission layer EML1, the second emission layer EML2, the third emission layer EML3, and the fourth emission layer EML4 may emit blue light. For example, one selected from the first emission layer EML1, the second emission layer EML2, the third emission layer EML3, and the fourth emission layer EML4 may be a green light emission layer, while the other three of the first emission layer EML1, the second emission layer EML2, the third emission layer EML3, and the fourth emission layer EML4 may be blue light emission layers.

In some embodiments, the fourth emission layer EML4 may be a green light emission layer, and the first emission layer EML1, the second emission layer EML2, and the third emission layer EML3 may all be blue light emission layers.

The fourth hole transport layer HTL4 may be located on the second charge generation layer CGL2. The fourth hole transport layer HTL4 may be made of the same material as the first hole transport layer HTL1 or may include one or more materials selected from the materials listed above as materials included in the first hole transport layer HTL1. The fourth hole transport layer HTL4 may be made of a single layer or multiple layers. When the fourth hole transport layer HTL4 is made of multiple layers, the layers may include different materials.

The third electron block layer BIL3 may be located on the fourth hole transport layer HTL4 and may be located between the fourth hole transport layer HTL4 and the fourth emission layer EML4. The third electron block layer BIL3 may be made of the same material and the same structure as the first electron block layer BIL1 or may include one or more materials selected from the materials listed above as the materials included in the first electron block layer BIL1 . In some alternative embodiments, the third electron block layer BIL3 may be omitted.

The fourth electron transport layer ELT4 may be located on the fourth emission layer EML4 and may be located between the third charge generation layer CGL3 and the fourth emission layer EML4. The fourth electron transport layer ETL4 may be made of the same material and the same structure as the first electron transport layer ETL1 or may include one or more materials selected from the materials listed above as the materials included in the first electron transport layer ETL1. The fourth electron transport layer ETL4 may be made of a single layer or multiple layers. When the fourth electron transport layer ETL4 is made of multiple layers, the layers may include different materials.

The third charge generation layer CGL3 may have the same structure as the first charge generation layer CGL1 described above. For example, the third charge generation layer CGL3 may include an n-type charge generation layer CGL31 located closer to the second stack ST2 and a p-type charge generation layer CGL32 located closer to the cathode electrode CE. The p-type charge generation layer CGL32 may be located on the n-type charge generation layer CGL31.

In some embodiments, an electron injection layer may be further located between the fourth stack ST4 and the third charge generation layer CGL3. In addition, a hole injection layer may be further located between the fourth stack ST4 and the second charge generation layer CGL2.

In some embodiments, both the emissive layer OL shown in FIG. 9 and the emissive layer OLa shown in FIG. 10 may not include a red light emission layer and thus may not emit the light of the first color, e.g., red light. That is, the exiting light LE may not include an optical component having a peak wavelength in the range of approximately 610 nm to 650 nm, and the exiting light LE may include only an optical component having a peak wavelength of 440 nm to 550 nm.

As shown in FIG. 11, a dam member DM may be located on the second insulating layer 117 in the non-display area NDA.

The dam member DM may be located more to the outside (e.g., the edge of the first base 110) than the voltage supply line VSL. In other words, as shown in FIG. 11, the voltage supply line VSL may be located between the dam member DM and the display area DA.

In some embodiments, the dam member DM may include a plurality of dams. For example, the dam member DM may include a plurality of dams. For example, the dam member DM may include a first dam D1 and a second dam D2.

The first dam D1 may partially overlap the voltage supply line VSL and may be spaced apart from the third insulating layer 130 with the voltage supply line VSL interposed therebetween. In some embodiments, the first dam D1 may include a first lower dam pattern D11 located on the second insulating layer 117 and a first upper dam pattern D12 located on the first lower dam pattern D11.

The second dam D2 may be located on the outer side of the first dam D1 (e.g., the second dam D2 is closer to the edge of the first base 110 than the first dam D1 is to the edge of the first base 110) and may be spaced apart from the first dam D1. In some embodiments, the second dam D2 may include a second lower dam pattern D21 located on the second insulating layer 117 and a second upper dam pattern D22 located on the second lower dam pattern D21.

In some embodiments, the first lower dam pattern D11 and the second lower dam pattern D21 may be made of the same material as the third insulating layer 130 and may be formed together with the third insulating layer 130.

In some embodiments, the first upper dam pattern D12 and the second upper dam pattern D22 may be made of the same material as the pixel-defining layer 150 and may be formed together with the pixel-defining layer 150.

In some embodiments, the height of the first dam D1 may be different from the height of the second dam D2. For example, the height of the second dam D2 may be greater than the height of the first dam D1. That is, the height of the dams included in the dam member DM may gradually increase away from the display area DA. Accordingly, it may be possible to more effectively block an organic matter from overflowing during a process of forming an organic layer 173 included by an encapsulation layer 170, which will be described in more detail later.

As shown in FIGS. 8 and 11, a first capping layer 160 may be located on the cathode electrode CE. The first capping layer 160 may be commonly located across the first emission area LA1, the second emission area LA2, the third emission area LA3, and the non-emission area NLA, so that viewing angle characteristics can be improved and the out-coupling efficiency can be increased.

The first capping layer 160 may include an inorganic material and/or an organic material having suitable light-transmitting properties. In other words, the first capping layer 160 may be formed as an inorganic layer, as an organic layer, or as an organic layer containing inorganic particles. For example, the first capping layer 160 may include a triamine derivative, a carbazole biphenyl derivative, an arylene diamine derivative, and/or an aluminum quinolinolate complex (Alq3).

In some embodiments, the first capping layer 160 may be made of a mixture of a high-refractive material and a low-refractive material. In some embodiments, the first capping layer 160 may include two layers having different refractive indices, for example, a high-refractive layer and a low-refractive layer.

In some embodiments, the first capping layer 160 may completely cover the cathode electrode CE. In some embodiments, as shown in FIG. 11, the end of the first capping layer 160 may be located more to the outside (e.g., the end of the first capping layer 160 is closer to the edge of the first base 110) than the end of the cathode electrode CE, and the end of the cathode electrode CE may be completely covered by the first capping layer 160.

The encapsulation layer 170 may be located on the first capping layer 160. The encapsulation layer 170 protects elements located under the encapsulation layer 170, for example, the light-emitting elements ED1, ED2 and ED3, from external foreign substances such as moisture. The encapsulation layer 170 is commonly located across the first emission area LA1, the second emission area LA2, the third emission area LA3, and the non-emission area NLA. In some embodiments, the encapsulation layer 170 may directly cover the cathode electrode CE (e.g., without the first capping layer 160). In some embodiments, a capping layer covering the cathode electrode CE may be further located between the encapsulation layer 170 and the cathode electrode CE, in which case the encapsulation layer 170 may directly cover the capping layer. The encapsulation layer 170 may be a thin-film encapsulation layer.

In some embodiments, the encapsulation layer 170 may include a lower inorganic layer 171, an organic layer 173, and an upper inorganic layer 175 which are sequentially stacked on the first capping layer 160.

In some embodiments, the lower inorganic layer 171 may cover the first light-emitting element ED1, the second light-emitting element ED2, and the third light-emitting element ED3 in the display area DA. The lower inorganic layer 171 may cover the dam member DM in the non-display area NDA and may be extended to the outside of (e.g., beyond) the dam member DM.

In some embodiments, the lower inorganic layer 171 may completely cover the first capping layer 160. In some embodiments, the end of the lower inorganic layer 171 may be located more to the outside (e.g., toward the edge of the first base 110) than the end of the first capping layer 160, and the end of the first capping layer 160 may be completely covered by the lower inorganic layer 171.

The lower inorganic layer 171 may include a plurality of stacked layers. The organic layer 173 may be located on the lower inorganic layer 171. The organic layer 173 may cover the first light-emitting element ED1, the second light-emitting element ED2, and the third light-emitting element ED3 in the display area DA. In some embodiments, a part of the organic layer 173 may be located in the non-display area NDA but may not be located outside the dam member DM. Although a part of the organic layer 173 is located more to the inside than the first dam D1 in the drawing, the present disclosure is not limited thereto. In some alternative embodiments, a part of the organic layer 173 may be accommodated in a space between the first dam D1 and the second dam D2, and the end of the organic layer 173 may be located between the first dam D1 and the second dam D2.

The upper inorganic layer 175 may be located on the organic layer 173. The upper inorganic layer 175 may cover the organic layer 173. In some embodiments, the upper inorganic layer 175 may be in direct contact with the lower inorganic layer 171 in the non-display area NDA to form an inorganic/inorganic junction. In some embodiments, the end of the upper inorganic layer 175 and the end of the lower inorganic layer 171 may be substantially aligned with each other. The upper inorganic layer 175 may include a plurality of stacked layers. A detailed structure of the upper inorganic layer 175 will be described below.

Each of the lower inorganic layer 171 and the upper inorganic layer 175 may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, and/or the like.

In some embodiments, the organic layer 173 may be made of acrylic resin, methacrylic resin, polyisoprene, vinyl resin, epoxy resin, urethane resin, cellulose resin and/or perylene resin.

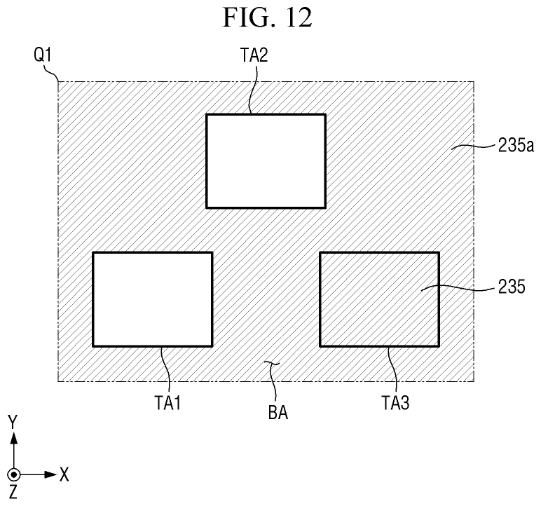

Hereinafter, the color conversion substrate 30 will be described with further reference to FIGS. 12 to 15 in conjunction to FIGS. 1 to 11.

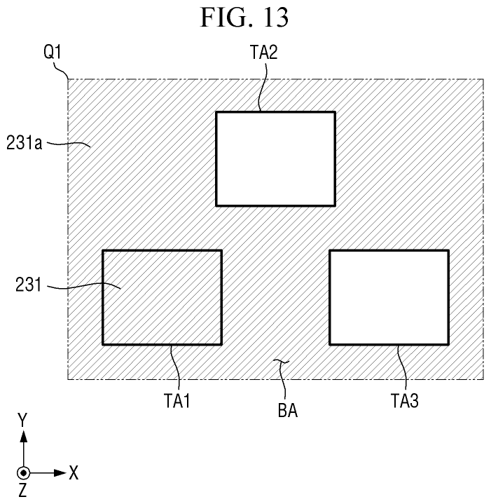

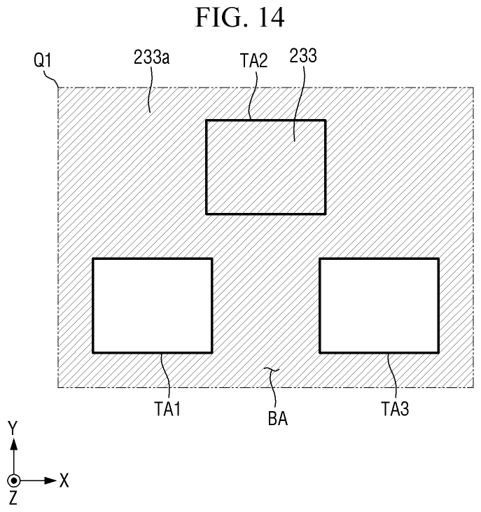

FIG. 12 is a plan view showing a layout of a third color filter on a color conversion substrate of a display device according to some embodiments of the present disclosure. FIG. 13 is a plan view showing a layout of a first color filter on the color conversion substrate of the display device according to some embodiments of the present disclosure. FIG. 14 is a plan view showing a layout of a second color filter on the color conversion substrate of the display device according to some embodiments of the present disclosure.

A second base 310 shown in FIGS. 8 and 11 may be made of a light-transmitting material.

In some embodiments, the second base 310 may include a glass substrate and/or a plastic substrate. In some embodiments, the second base 310 may further include a separate layer located on the glass substrate and/or the plastic substrate, e.g., an insulating layer such as an inorganic film.

In some embodiments, a plurality of light-transmitting areas TA1, TA2 and TA3 and a light-blocking area BA may be defined on the second base 310. When the second base 310 includes a glass substrate, the refractive index of the second base may be approximately 1.5.

As shown in FIGS. 8 and 11, a color filter layer may be disposed on a surface of the second base 310 facing the display substrate 10. The color filter layer may include color filters 231, 233, and 235 and a light-blocking pattern 250.

As shown in FIGS. 8, 11, and 12 to 14, the color filters 231, 233, and 235 may overlap the light-transmitting areas TA1, TA2, and TA3, respectively. The light-blocking pattern 250 may be disposed to overlap the light-blocking area BA. The first color filter 231 may overlap a first light-transmitting area TA1, the second color filter 233 may overlap a second light-transmitting area TA2, and the third color filter 235 may overlap a third light-transmitting area TA3. The light-blocking pattern 250 may be disposed to overlap the light-blocking area BA to block transmission of light. In some embodiments, the light-blocking pattern 250 may be arranged in a substantially lattice formation when viewed from the top (e.g., in a plan view). According to an embodiment, the light-blocking pattern 250 may include a first light-blocking pattern portion 235a on a surface of the second base 310, a second light-blocking pattern portion 231a on the first light-blocking pattern portion 235a, and a third light-blocking pattern portion 233a on the second light-blocking pattern portion 231a. The first light-blocking pattern portion 235a may include the same material as the third color filter 235, and the second light-blocking pattern portion 231a may include the same material as the first color filter 231, and the third light-blocking pattern portion 233a may include the same material as the second color filter 233. That is, the light-blocking pattern 250 may include a structure in which the first light-blocking pattern portion 235a, the second light-blocking pattern portion 231a, and the third light-blocking pattern portion 233a are sequentially stacked on one surface of the second base 310 in the light-blocking area BA. In the case where the light-blocking pattern 250 has a structure in which the first light-blocking pattern portion 235a, the second light-blocking pattern portion 231a, and the third light-blocking pattern portion 233a are sequentially stacked on one surface of the second base 310 in the light-blocking area BA, when external light La is incident onto the light-blocking area BA, light of the first color and light of the second color may all be absorbed by the first light-blocking pattern portion 235a except for light of the third color while passing through the first light-blocking pattern portion 235a. In addition, the light of the third color may also be absorbed by the second and third light-blocking portions 231a and 233a while passing through the second and third light-blocking portions 231a and 233a. However, in an embodiment, a portion of the external light La may not be transmitted by the first light-blocking pattern portion 235a and may be reflected to the outside at the interface between the first light-blocking pattern portion 235a and the second base 310. In this case, the light may be light of the third color.

In some embodiments, the light-blocking pattern 250 may include an organic light-blocking material, and may be formed via processes of coating and exposing the organic light-blocking material. For example, the organic light-blocking material may include a black matrix.

The first color filter 231 may work as a blocking filter that blocks blue light and green light. In some embodiments, the first color filter 231 may selectively transmit the light of the first color (e.g., red light) while blocking or absorbing the light of the second color (e.g., green light) and the light of the third color (e.g., blue light). For example, the first color filter 231 may be a red color filter and may include a red colorant. The first color filter 231 may include a base resin and a red colorant dispersed in the base resin.

The second color filter 233 may work as a blocking filter that blocks blue light and red light. In some embodiments, the second color filter 233 may selectively transmit the light of the second color (e.g., green light) while blocking or absorbing the light of the third color (e.g., blue light) and the light of the first color (e.g., red light). For example, the second color filter 233 may be a green color filter and may include a green colorant.

The third color filter 235 may selectively transmit the light of the third color (e.g., blue light) while blocking or absorbing the light of the first color (e.g., red light) and the light of the second color (e.g., green light). In some embodiments, the third color filter 235 may be a blue color filter and may include a blue colorant such as a blue dye and/or a blue pigment. As used herein, a colorant encompasses a dye as well as a pigment.

As shown in FIGS. 8 and 11, a low refractive index layer 391 covering the light-blocking pattern 250, the first color filter 231, the second color filter 233, and the third color filter 235 may be located on a surface of the second base 310. In some embodiments, the low refractive index layer 391 may be in direct contact with the first color filter 231, the second color filter 233, and the third color filter 235. In addition, according to some embodiments, the low refractive index layer 391 may also be in direct contact with the light-blocking pattern 250.

The low refractive index layer 391 may have a lower refractive index than a wavelength conversion patterns 340 and 350 and a light-transmitting pattern 330. For example, the low refractive index layer 391 may be made of an inorganic material. For example, the low refractive index layer 391 may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, etc. In some embodiments, the low refractive index layer 391 may include a plurality of hollow particles to lower the refractive index.

A low refractive index capping layer 392 may be further disposed between the low refractive index layer 391 and the wavelength conversion patterns 340 and 350 and between the low refractive index layer 391 and the light-transmitting pattern 330. In some embodiments, the low refractive index capping layer 392 may be in direct contact with the wavelength conversion patterns 340 and 350 and the light-transmitting pattern 330. In addition, according to some embodiments, the low refractive index capping layer 392 may also be in direct contact with the bank pattern 370.

The low refractive index capping layer 392 may have a lower refractive index than the wavelength conversion patterns 340 and 350 and the light-transmitting pattern 330. For example, the low refractive index capping layer 392 may be made of an inorganic material. For example, the low refractive index capping layer 392 may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, etc. In some embodiments, the low refractive index capping layer 392 may include a plurality of hollow particles to lower the refractive index.

The low refractive index capping layer 392 may prevent or reduce instances of the first color filter 231, the second color filter 233, and the third color filter 235 being damaged and/or contaminated by impurities such as moisture and/or air introduced from the outside. In addition, the low refractive index capping layer 392 may prevent or reduce instances of the colorant contained in the first color filter 231, the second color filter 233, and the third color filter 235 diffusing into other elements, e.g., a first wavelength conversion pattern 340 and a second wavelength conversion pattern 350, etc.

In some embodiments, the low refractive index layer 391 and the low refractive index capping layer 392 may cover side surfaces of the light-blocking pattern 250 in the non-display area NDA. In addition, according to some embodiments, the low refractive index capping layer 392 may be in direct contact with the second base 310 in the non-display area NDA.

The bank pattern 370 may be located on a surface of the low refractive index capping layer 392 facing the display substrate 10. In some embodiments, the bank pattern 370 may be located directly on the surface of the low refractive index capping layer 392 and may be in direct contact with the low refractive index capping layer 392.

In some embodiments, the bank pattern 370 may be disposed to overlap the non-emission area NLA or the light-blocking area BA. In some embodiments, as shown in FIG. 15, the bank pattern 370 may be around (e.g., surround) the first light-transmitting area TA1, the second light-transmitting area TA2, and the third light-transmitting area TA3 when viewed from the top (e.g., in a plan view). The bank pattern 370 may define the space where each of the first wavelength conversion pattern 340, the second wavelength conversion pattern 350, and a light-transmitting pattern 330 is formed.

In some embodiments, the bank pattern 370 may be implemented as a single pattern which is a single piece, but the present disclosure is not limited thereto. In an alternative embodiment, a part of the bank pattern 370 around (e.g., surrounding) the first light-transmitting area TA1, a part of the bank pattern 370 around (e.g., surrounding) the second light-transmitting area TA2, and a part of the bank pattern 370 around (e.g., surrounding) the third light-transmitting area TA3 may be formed as individual patterns separate from one another.

When the first wavelength conversion pattern 340, the second wavelength conversion pattern 350, and the light-transmitting pattern 330 are formed by a method of ejecting an ink composition utilizing a nozzle, that is, an inkjet printing method, the bank pattern 370 may serve as a guide that stably positions the ejected ink composition at a desired position. That is, the bank pattern 370 may function as a barrier rib.

In some embodiments, the bank pattern 370 may overlap the pixel-defining layer 150.

As shown in FIG. 11, in some embodiments, the bank pattern 370 may be further located in the non-display area NDA. The bank pattern 370 may overlap the light-blocking pattern 250 in the non-display area NDA.

In some embodiments, the bank pattern 370 may include an organic material having photocurability. In addition, according to some embodiments, the bank pattern 370 may include an organic material having photocurability and including a light-blocking material. In the case where the bank pattern 370 has light-blocking properties, the bank pattern 370 may prevent or substantially prevent light from intruding (e.g., mixing) between neighboring emission areas in the display area DA. For example, the bank pattern 370 may block the exiting light LE emitted from the second light emitting element ED2 from entering the first wavelength conversion pattern 340 overlapping the first emission area LA1. In addition, the bank pattern 370 may block or prevent external light from entering elements located under the bank pattern 370 in the non-emission area NLA and the non-display area NDA.

As shown in FIGS. 8 and 11, the first wavelength conversion pattern 340, the second wavelength conversion pattern 350, and the light-transmitting pattern 330 may be located on a lower portion of the low refractive index layer 391. In some embodiments, the first wavelength conversion pattern 340, the second wavelength conversion pattern 350, and the light-transmitting pattern 330 may be located in the display area DA.

The light-transmitting pattern 330 may overlap the third emission area LA3 and the third light-emitting element ED3. The light-transmitting pattern 330 may be located in the space defined by the bank pattern 370 in the third light-transmitting area TA3.

In some embodiments, the light-transmitting pattern 330 may be formed as an island-shaped pattern. It is illustrated in the drawing that the light-transmitting pattern 330 does not overlap the light-blocking area BA, but the present disclosure is not limited thereto. In alternative embodiments, a part of the light-transmitting pattern 330 may overlap the light-blocking area BA.

The light-transmitting pattern 330 may transmit incident light. Exiting light LE provided by the third light-emitting element ED3 may be blue light as described above. The exiting light LE, which is blue light, passes through the light-transmitting pattern 330 and the third color filter 230 and exits (e.g., is emitted) to the outside of the display device 1. That is, the third light L3 emitted from the third emission area LA3 to the outside of the display device 1 may be blue light.

In some embodiments, the light-transmitting pattern 330 may include a third base resin 331 and may further include third scatterers 333 dispersed in the third base resin 331. Hereinafter, base resins, scatterers, and/or wavelength shifters which are included in the light-transmitting pattern 330 and the wavelength conversion patterns 340 and 350 are referred by the ordinal numbers of “first,” “second,” and “third” to distinguish between the elements of the light-transmitting pattern 330 and the wavelength conversion patterns 340 and 350. However, the ordinal numbers of “first,” “second,” and “third” as used herein to refer to the respective elements of the light-transmitting pattern 330 and the wavelength conversion patterns 340 and 350 are not limited thereto, and the order thereof may be changed to refer to the respective elements.

The third base resin 331 may be made of a material with a high light transmittance. In some embodiments, the third base resin 331 may be formed of an organic material. For example, the third base resin 331 may include an epoxy-based resin, an acrylic-based resin, a cardo-based resin, and/or an imide-based resin.

The third scatterers 333 may have a refractive index different from that of the third base resin 331 and may form an optical interface with the third base resin 331. For example, the third scatterers 333 may be light scattering particles. The material of the third scatterers 333 is not particularly limited as long as they can scatter at least a part of the transmitted light. For example, the third scatterers 333 may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include acrylic-based resins, urethane-based resins, etc. For example, the third scatterers 333 according to the embodiment may include titanium oxide (TiO₂).

The third scatterers 333 may scatter light in random directions regardless of the direction in which the incident light is coming, without substantially changing the wavelength of the light transmitted through the light-transmitting pattern 330. In some embodiments, the light-transmitting pattern 330 may be in direct contact with the bank pattern 370.

The first wavelength conversion pattern 340 may overlap the first emission area LA1, the first light-emitting element ED1, or the first light-transmitting area TA1.

In some embodiments, the first wavelength conversion pattern 340 may be located in a space defined by the bank pattern 370 in the first light-transmitting area TA1.

In some embodiments, the first wavelength conversion pattern 340 may be formed in an island shape pattern as shown in FIG. 15. It is illustrated in the drawing that the first wavelength conversion pattern 340 does not overlap the light-blocking area BA, but the present disclosure is not limited thereto. In alternative embodiments, a part of the first wavelength conversion pattern 340 may overlap the light-blocking area BA. In some embodiments, the first wavelength conversion pattern 340 may be in direct contact with the bank pattern 370.

The first wavelength conversion pattern 340 may convert or shift the peak wavelength of the incident light into light of another peak wavelength through first wavelength shifters 345 (to be described in more detail later) and emit the light. In some embodiments, the first wavelength conversion pattern 340 may convert the exiting light LE provided from the first light-emitting element ED1 into red light having a peak wavelength in the range of 610 to 650 nm.

In some embodiments, the first wavelength conversion pattern 340 may include the first base resin 341 and the first wavelength shifters 345 dispersed in the first base resin 341, and may further include the first scatterers 343 dispersed in the first base resin 341.

The first base resin 341 may be made of a material with a high light transmittance. In some embodiments, the first base resin 341 may be formed of an organic material. In some embodiments, the first base resin 341 may be made of the same material as the third base resin 331, or may include at least one of the materials listed above as the examples of the constituent materials of the third base resin 331.

Examples of the first wavelength shifters 345 may include quantum dots, quantum bars, and/or phosphors. For example, quantum dots may be particulate matter that emits a specific color as electrons transition from the conduction band to the valence band.

The quantum dots may be a semiconductor nanocrystalline material. The quantum dots have a specific band gap depending on their compositions and size, and can absorb light and then emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, or combinations thereof.

The group II-VI compounds may be selected from the group consisting of: binary compounds selected from the group consisting of CdSe, CdTe, ZnS, ZnSe, ZnTe, ZnO, HgS, HgSe, HgTe, MgSe, MgS and a mixture thereof; ternary compounds selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-V compounds may be selected from the group consisting of: binary compounds selected from the group consisting of GaN, GaP, GaAs, GaSb, AlN, AlP, AlAs, AlSb, InN, InP, InAs, InSb and a mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, and a mixture thereof; and quaternary compounds selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The group IV-VI compounds may be selected from the group consisting of: binary compounds selected from the group consisting of SnS, SnSe, SnTe, PbS, PbSe, PbTe and a mixture thereof; ternary compounds selected from the group consisting of SnSeS, SnSeTe, SnSTe, PbSeS, PbSeTe, PbSTe, SnPbS, SnPbSe, SnPbTe, and a mixture thereof; and quaternary compounds selected from the group consisting of SnPbSSe, SnPbSeTe, SnPbSTe and a mixture thereof. The group IV elements may be selected from the group consisting of Si, Ge and a mixture thereof. The group IV compounds may be binary compounds selected from the group consisting of SiC, SiGe and a mixture thereof.

The binary compounds, the ternary compounds, or the quaternary compounds may be present in the particles at a uniform concentration, or may be present in the same particles at partially different concentrations. In addition, they may have a core/shell structure in which one quantum dot is around (e.g., surrounds) another quantum dot. At the interface between the core and the shell, there may be a concentration gradient where the concentration of atoms in the shell may decrease toward the center of the core.

In some embodiments, the quantum dots may have a core-shell structure including a core comprising the aforementioned nanocrystals and a shell around (e.g., surrounding) the core. The shell of the quantum dots may serve as a protective layer for maintaining the semiconductor properties by preventing or reducing instances of chemical denaturation of the core and/or as a charging layer for imparting electrophoretic properties to the quantum dots. The shell may be either a single layer or multiple layers. At the interface between the core and the shell, a gradient where the concentration of atoms in the shell decreases toward the center of the core may exist. Examples of the shell of the quantum dot may include an oxide of a metal or a non-metal, a semiconductor compound, a combination thereof, etc.

For example, examples of the metal or non-metal oxide may include, but is not limited to, binary compounds such as SiO₂, Al₂O₃, TiO2, ZnO, MnO, Mn₂O₃, Mn₃O₄, CuO, FeO, Fe₂O₃, Fe₃O₄, CoO, Co₃O₄ and/or NiO, and/or ternary compounds such as MgAl₂O₄, CoFe₂O₄, NiFe₂O₄ and/or CoMn₂O₄.

Examples of the semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

The light output from the first wavelength shifters 345 may have a full width at half maximum (FWHM) of the emission wavelength spectrum of approximately 45 nm or less, approximately 40 nm or less, or approximately 30 nm or less. In this manner, the color purity and color reproducibility of the colors displayed by the display device 1 can be further improved. In addition, the light output from the first wavelength shifters 345 may travel in different directions regardless of the incidence direction of the incident light. In this way, the side visibility of the first color displayed in the first light-transmitting area TA1 can be improved.

A part of the exiting light LE provided from the first light-emitting element ED1 may not be converted into red light by the first wavelength shifters 345 but may pass (e.g., penetrate) through the first wavelength conversion pattern 340. Components of the exiting light LE which are not converted by the first wavelength conversion pattern 340 but are incident on the first color filter 231 may be blocked by the first color filter 231. On the other hand, red light that is converted from the exiting light LE by the first wavelength conversion pattern 340 passes through the first color filter 231 to exit (e.g., to be emitted) to the outside. That is, first light L1 exiting (e.g., emitted) to the outside of display device 1 through the first light-transmitting area TA1 may be red light.

The first scatterers 343 may have a refractive index different from that of the first base resin 341 and may form an optical interface with the first base resin 341. For example, the first scatterers 343 may be light scattering particles. The first scatterers 343 are substantially identical to the third scatterers 333 described above; and, therefore, the redundant description will be omitted.

The second wavelength conversion pattern 350 may be located in the space defined by the bank pattern 370 in the second light-transmitting area TA2.

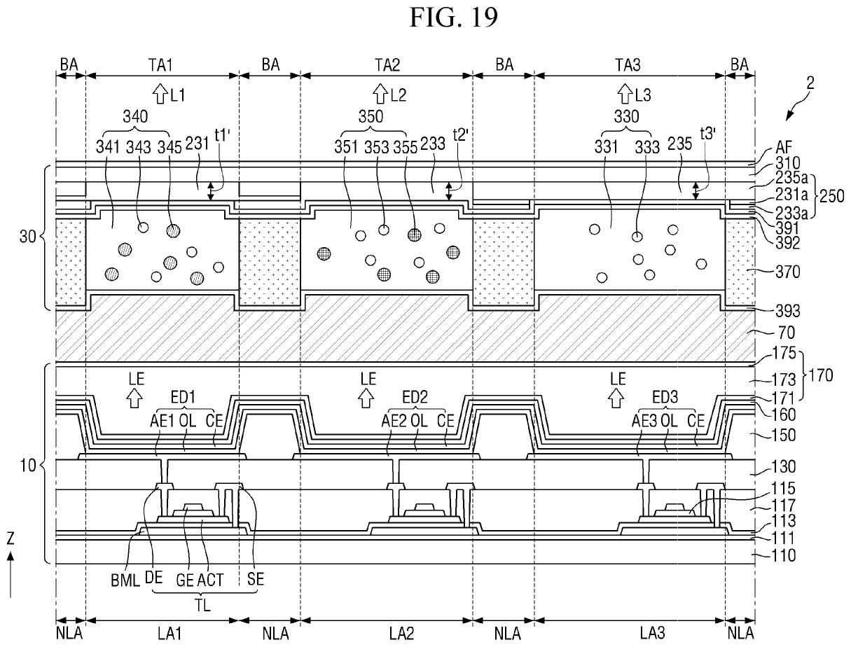

In some embodiments, the second wavelength conversion pattern 350 may be formed in an island shape pattern as shown in FIG. 19. In some embodiments, unlike what is illustrated in the drawing, a part of the second wavelength conversion pattern 350 may overlap the light-blocking area BA. In some embodiments, the second wavelength conversion pattern 350 may be in direct contact with the bank pattern 370.

The second wavelength conversion pattern 350 may convert or shift the peak wavelength of the incident light into light of another peak wavelength through second wavelength shifters 355 to be described in more detail later and emit the light. In some embodiments, the second wavelength conversion pattern 350 may convert the exiting light LE provided from the second light-emitting element ED2 into green light in the range of approximately (about) 510 nm to (about) 550 nm.

In some embodiments, the second wavelength conversion pattern 350 may include a second base resin 351 and the second wavelength shifters 355 dispersed in the second base resin 351, and may further include second scatterers 353 dispersed in the second base resin 351.

The second base resin 351 may be made of a material with a high light transmittance. In some embodiments, the second base resin 351 may be formed of an organic material. In some embodiments, the second base resin 351 may be made of the same material as the third base resin 331, or may include at least one of the materials listed above as the examples of the constituent materials of the third base resin 331.

Examples of the second wavelength shifters 355 may include quantum dots, quantum bars, and/or phosphors. The second wavelength shifters 355 are substantially identical to the first wavelength shifters 345; and, therefore, the redundant description will be omitted.

In some embodiments, the first wavelength shifters 345 and the second wavelength shifters 355 may all be made of quantum dots. In such case, the particle size of the quantum dots forming the second wavelength shifters 355 may be smaller than the particle size of the quantum dots forming the first wavelength shifters 345.

The second scatterers 353 may have a refractive index different from that of the second base resin 351 and may form an optical interface with the second base resin 351. For example, the second scatterers 353 may be light scattering particles. The second scatterers 353 are substantially identical to the first scatterers 343 described above; and, therefore, the redundant description will be omitted.

The exiting light LE emitted from the third light-emitting element ED3 may be provided to the second wavelength conversion pattern 350. The second wavelength shifters 355 may convert the exiting light LE provided from the third light-emitting element ED3 into green light having a peak wavelength in the range of approximately (about) 510 nm to (about) 550 nm.

A part of the exiting light LE, which is blue light, may not be converted into green light by the second wavelength shifters 355 but may pass (e.g., penetrate) through the second wavelength conversion pattern 350, which may be blocked by the second color filter 223. On the other hand, green light that is converted from the exiting light LE by the second wavelength conversion pattern 350 passes through the second color filter 233 to exit (e.g., to be emitted) to the outside. Accordingly, second light L2 exiting (e.g., emitted) to the outside of the display device 1 from the second light-transmitting area TA2 may be green light.

In some embodiments, the third capping layer 393 may be around (e.g., surround) the outer surfaces of the bank pattern 370 in the non-display area NDA. In addition, the third capping layer 393 may be in direct contact with the low refractive index capping layer 392 in the non-display area NDA.

In some embodiments, the third capping layer 393 may be made of an inorganic material. In some embodiments, the third capping layer 393 may be made of the same material as the low refractive index layer 391 or may include at least one of those listed above as the materials of the low refractive index layer 391. When both (e.g., simultaneously) the low refractive index layer 391 and the third capping layer 393 are made of an inorganic material, in the non-display area NDA, the low refractive index layer 391 and the third capping layer 393 may be in direct contact with each other to form an inorganic-inorganic junction.

As described above, in the non-display area NDA, the sealing member 50 may be located between the color conversion substrate 30 and the display substrate 10.

The sealing member 50 may overlap the encapsulation layer 170. For example, the sealing member 50 may overlap the lower inorganic layer 171 and the upper inorganic layer 175 and may not overlap the organic layer 173. In some embodiments, the sealing member 50 may be in direct contact with the encapsulation layer 170. For example, the sealing member 50 may be located directly on the upper inorganic layer 175 and may be in direct contact with the upper inorganic layer 175.

In some embodiments, the upper inorganic layer 175 and the lower inorganic layer 171 located below the sealing member 50 may be extended to the outside of (e.g., beyond) the sealing member 50.

The sealing member 50 may overlap the light-blocking pattern 250, the first color filter 231, and the bank pattern 370 in the non-display area NDA. In some embodiments, the sealing member 50 may be in direct contact with the capping layer 393 covering the bank pattern 370.

The sealing member 50 may overlap the first gate metal WR1 including the lines and/or the like connected to the connection pad PD. As the sealing member 50 is disposed to overlap the first gate metal WR1, the width of the non-display area NDA may be reduced.

The filler 70 may be located in the space defined by the color conversion substrate 30, the display substrate 10, and the sealing member 50, as described above. In some embodiments, the filler 70 may be in direct contact with the capping layer 393 and the upper inorganic layer 175 of the encapsulation layer 170, as shown in FIGS. 8 and 11.

An anti-reflective film (AF) may be further disposed on a surface of the second base 310 of the display device 1 according to an embodiment opposite to the surface in contact with the color filters 231, 233, and 235. The anti-reflective film AF disposed on the surface of the second base 310 opposite to the surface in contact with the color filters 231, 233, and 235 may reduce or minimize input (e.g., entering) of external light into the display device 1. The anti-reflective film AF may include a first surface located on the display surface and a second surface (surface in contact with the second base 310) opposite to the first surface, and may reduce or minimize input (e.g., entering) of external light into the display device 1 by utilizing a principle of mutually interfering the external light reflected from the first surface and the external light reflected from the second surface. In some embodiments, the anti-reflective film AF may be made of a plurality of layers with adjusted refractive indices, but the present disclosure is not limited thereto.

FIG. 15 is a schematic diagram showing reflection of external light by a display device according to an embodiment of the present disclosure.

Referring to FIG. 15, in the display device 1 according to an embodiment, even when the above-described anti-reflective film AF is disposed and the light-blocking pattern 250 is disposed on the light-blocking area BA, there is a limit in controlling the reflection of external light incident from the outside of the display device 1. Even when the light-blocking pattern 250 is disposed on the light-blocking area BA, there is a limit in controlling the reflection of external light incident from the outside of the display device 1 because a portion (e.g., light of the third color) of the external light may not be transmitted by the first light-blocking pattern portion 235a and may be reflected to the outside at the interface between the first light-blocking pattern portion 235a and the second base 310 as described above and also because the ratio of the light of the third color to the reflected light varies according to the amount of the light-blocking area BA. The external light LO incident through the light-transmitting areas TA1, TA2, and TA3 may be reflected to the outside through various interfaces and/or members as shown in FIG. 15. The reflected light of the external light LO incident through the light-transmitting areas TA1, TA2, and TA3 may include reflective (e.g., reflected) light LR1 that is not canceled by mutual interference with the light reflected from the first surface of the anti-reflective film AF among the light reflected at the interface between the anti-reflective film AF and the second base 310, reflective (e.g., reflected) light LR2 reflected at the interface between the second base 310 and the color filters 231, 233, and 235, reflective (e.g., reflected) light LR3 reflected at the interface between the low refractive index capping layer 392 and the wavelength conversion patterns 340 and 350 and the interface between the low refractive index capping layer 392 and the light-transmitting pattern 330, reflective (e.g., reflected) light LR4 scattered and reflected by the wavelength shifters 345 and 355 in the wavelength conversion patterns 340 and 350, reflective (e.g., reflected) light LR5 reflected by the anode electrodes AE1, AE2, and AE3 and reflected to the outside without being in contact with the scatterers 333, 343, and 353 and/or the wavelength shifters 345 and 355, and reflective (e.g., reflected) light LR6 reflected by the anode electrodes AE1, AE2, and AE3 and reflected and scattered by the wavelength conversion patterns 340 and 350 and/or the scatterers 333, 343, and 353 of light-transmitting pattern 330.

The above-described reflective light may change a reflection color of the display device 1. For example, when a screen (or a display screen) of the display device 1 is turned off (the display device 1 is not driven), neutral black NB should be realized in which the screen of the display device 1 is displayed in black. That is, in order to realize neutral black NB in which the screen of the display device 1 is displayed in black when the display device 1 is not driven, the display device 1 has no reflection due to external light La (see, e.g., FIG. 8) or LO, or the sum of the colors of the reflective light caused by the external light La or LO should be neutral black. As described above, because a portion of the light (e.g., light of the third color) that is not transmitted by the first light-blocking pattern 255a and is reflected to the outside at the interface between the first light-blocking pattern 235a and the second base 310 and the reflective light caused by the external light LO incident through the light-transmitting areas TA1, TA2, and TA3 are (e.g., inevitably) generated, it may be difficult or impossible to realize a state in which there is no reflection due to the external light La or LO. Therefore, it is desirable or necessary to consider a method and/or approach by which the sum of the colors (or reflected color) of the reflective light of the external light La or LO becomes neutral black.

Factors that determine the reflected color may include the area of the above-described light-blocking area BA, the reflective light LR4 scattered and reflected by the wavelength shifters 345 and 355 in the wavelength conversion patterns 340 and 350, the reflective light LR6 reflected by the anode electrodes AE1, AE2, and AE3 and scattered and reflected by the wavelength conversion patterns 340 and 350 and/or the scatterers 333, 343, and 353 of the light-transmitting pattern 330, and the reflective light LR2 reflected at the interface between the second base 310 and the color filters 231, 233, and 235. Furthermore, the factors that determine the reflected color of the reflective light LR2, LR4, and LR6 may include a transmittance according to the thicknesses of the color filters 231, 233, and 235, the types or kinds of the color filters 231, 233, and 235, the areas of the color filters 231, 233, and 235 (or the areas Si, S2, and S3 of the light-transmitting areas TA1, TA2, and TA3), etc. Because the area of the light-blocking area BA described above is directly associated with the areas of the color filters 231, 233, and 235 (or the areas S1, S2, and S3 of the light-transmitting areas TA1, TA2, and TA3), a description of the area of the light-blocking area BA may be referred to the description of the areas of the color filters 231, 233, and 235 (or the areas S1, S2, and S3 of the light-transmitting areas TA1, TA2, and TA3).

There is however a limit in controlling the reflected color by adjusting the types or kinds and thicknesses of the color filters 231, 233, and 235. For example, the thicknesses t1, t2, and t3 (see, e.g., FIG. 8) of the color filters 231, 233, and 235 are related to (e.g., are chosen according to) the color gamut of the display device 1, and the color gamut of the display device 1 is preset. For example, the color gamut (%) of the display device 1 according to an embodiment may be preset to 90.2 to 90.6 in a BT2020 region. In some embodiments, in a DCI region, the color gamut (%) of the display device 1 may be preset to 99.9. In order to set the color gamut (%) of the display device 1 to 90.2 to 90.6, the color filters 231, 233, and 235 of the display device 1 may be configured to have set or predetermined thicknesses t1, t2, and t3, respectively. In some embodiments, the thickness t1 of the first color filter 231 may be greater than the thickness t2 of the second color filter 233, and the thickness t2 of the second color filter 233 may be greater than the thickness t3 of the third color filter 235. In some embodiments, the thickness t1 of the first color filter 231 may be 4.0 μm to 4.4 μm, the thickness t2 of the second color filter 233 may be 3.0 μm to 3.4 μm, and the thickness t3 of the third color filter 235 may be 2.8 μm to 3.2 μm.

Thus, the areas of the color filters 231, 233, and 235 (or the areas S1, S2, and S3 of the light-transmitting areas TA1, TA2, and TA3) among the factors determining the reflected color of the reflective light LR2, LR4, and LR6 should be taken into account. That is, by determining the areas of the color filters 231, 233, and 235 (or the areas S1, S2, and S3 of the light-transmitting areas TA1, TA2, and TA3), it is possible to derive the reflected color of the display device 1 which satisfies neutral black when the display device 1 is not driven (a color difference is also related).

The reflected color of the display device 1 which satisfies neutral black when the display device 1 is not driven may be derived (e.g., achieved) by satisfying the reflectance of each color of each reflective light and/or the reflectance ratio of each color of each reflective light. In the present disclosure, the reflectance ratio of a color of each reflective light may refer to a ratio of light of a specific color to the reflective light including the light of the first color, the light of the second color, and the light of the third color. That is, the sum of the reflectance ratio of the light of the first color, the reflectance ratio of the light of the second color, and the reflectance ratio of the light of the third color may be 100%. As described above, the reflectance of each color and/or the reflectance ratio of each color of each reflective light may be obtained by adjusting the areas of the color filters 231, 233, and 235 (or the areas S1, S2, and S3 of the light-transmitting areas TA1, TA2, and TA3. Meanwhile, the reflective light may have a set or predetermined reflectance of the light of the first color, a set or predetermined reflectance of the light of the second color, and a set or predetermined reflectance of the light of the third color. In addition, the reflective light may have a reflection ratio between the set or predetermined reflectance of the light of the first color, the set or predetermined reflectance of the light of the second color, and the set or predetermined reflectance of the light of the third color. In the present disclosure, the reflectance of each color and/or the reflectance ratio of each color of each reflective light may be measured in specular component included (SCI) mode. Measurement in SCI mode may be performed by a reflectance measurement device. The reflectance measurement device may include CM-2600D, CM-700D, or CM-3700A. The measurement in SCI mode may be performed by irradiating a measurement light source from the reflectance measurement device on the other side (e.g., the side opposite to the side facing the display device 1) of the second base 310 and measuring a reflectance of reflective light received by the reflectance measurement device. In this case, the measurement light source may include standard illuminant A, standard illuminant B, standard illuminant C, standard illuminant D, standard illuminant D50, standard illuminant D65, standard illuminant D75, standard illuminant E, or standard illuminant F. For example, the measurement light source may be standard illuminant C or D65. The standard illuminant C represents the average daylight (with a correlated color temperature of 6800 K), and the standard illuminant D65 represents average northern sunlight (with a correlated color temperature of 6500 K).

In some embodiments, the display device 1 according to an embodiment may have the reflected color that satisfies neutral black when the display device 1 is not driven, and as well as have a color difference ΔEab of 3 or less. The color difference ΔEab of the reflected color measured by a spectrochromometer is 3 or less, and the color difference ΔEab is calculated by Equation 1 below.

ΔEab={(ΔL*)2+(Δa*)2+(Δb*)2}1/2 [Equation 1]

In Equation 1, L*, a*, and b* are colorimetric values in CIE 1931 space measured utilizing the spectrochromometer under the conditions of an illuminant and 2° viewing angle.

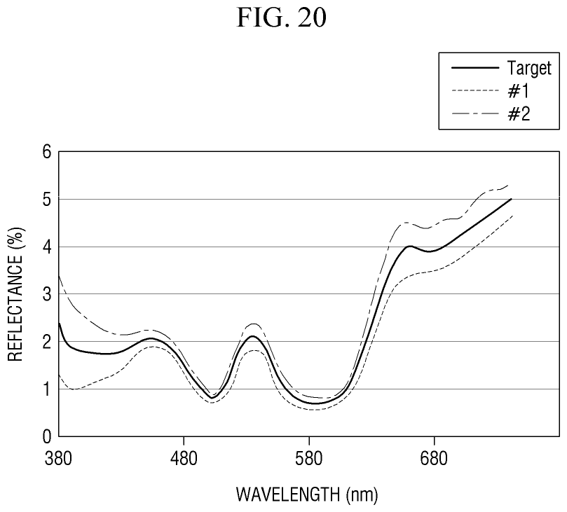

According to an embodiment, as will be described with reference to FIG. 20 in more detail, a reflectance (%) of the light of the first color at 460 nm, at which the condition is satisfied that the color difference ΔEab is 3 or less, or the reflected color viewed when the display device 1 is not driven satisfies neutral black, may be 1.8 to 2.2, a reflectance (%) of the light of the second color at 540 nm at which the above condition is satisfied may be 1.7 to 2.3, and a reflectance (%) of the light of the third color at 640 nm at which the same condition is satisfied may be 2.8 to 3.8.

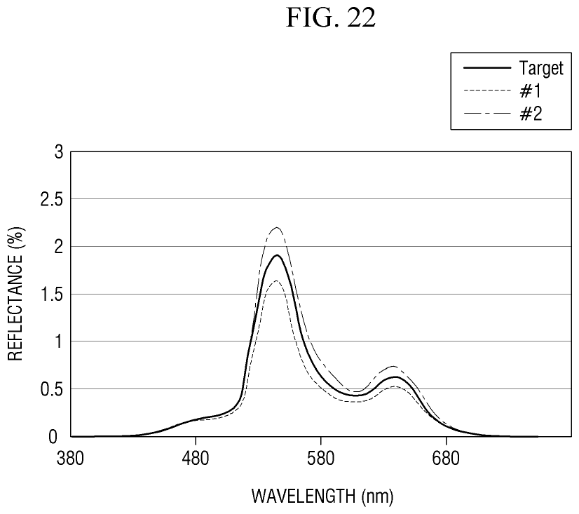

In some embodiments, as will be described with reference to FIG. 22 in more detail, the reflectance ratio (%) of the light of the first color, the reflectance ratio (%) of the light of the second color, and the reflectance ratio (%) of the light of the third color, at each of which the conditions are satisfied that a color difference ΔEab is 3 or less, as well as the reflected color viewed when the display device 1 is not driven satisfies neutral black, may be 5.3 to 9.2, 67.6 to 73.6, and 18.3 to 24.7, respectively.

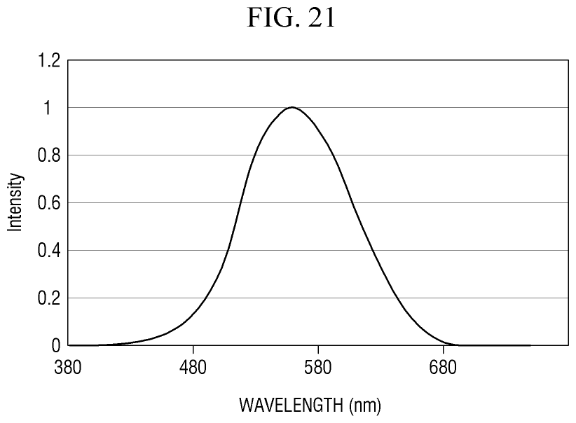

Here, 5.3 to 9.2, 67.6 to 73.6, and 18.3 to 24.7, which are obtained as, respectively, the reflectance ratio (%) of the light of the first color, the reflectance ratio (%) of the light of the second color, and the reflectance ratio (%) of the light of the third color, at each of which the conditions are satisfied that a color difference ΔEab is 3 or less, as well as the reflected color viewed when the display device 1 is not driven satisfies neutral black, may be calculated from the derived reflectance ratio (%) of the light of the first color, the derived reflectance ratio (%) of the light of the second color, and the derived reflectance ratio (%) of the light of the third color, respectively, by taking into account a visibility curve (see FIG. 21).

The reflectance of each color of the reflective light and/or the reflectance ratio of each color of the reflective light for the reflected color that satisfies neutral black when the display device 1 is not driven will be described in greater detail below.

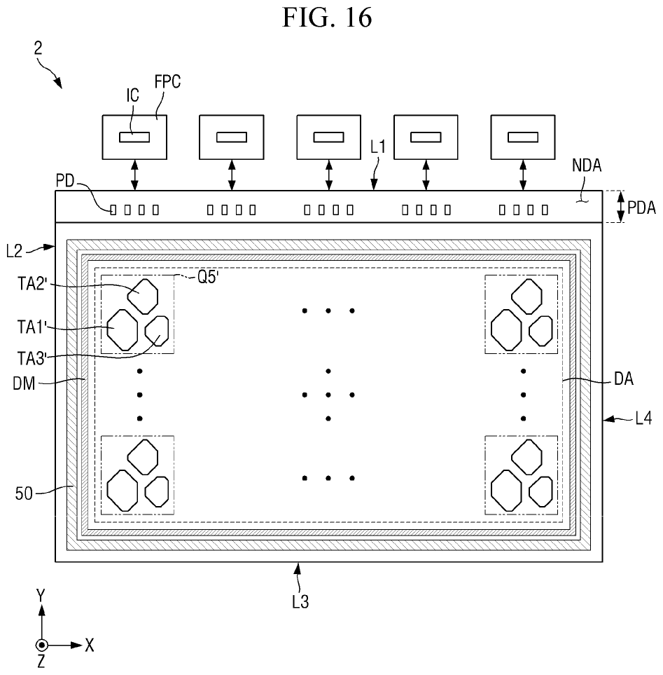

Hereinafter, a display device 2 according to another embodiment will be described with reference to FIGS. 16 to 19. When description is made with reference to FIGS. 16 to 19, like reference numerals are used for like or corresponding elements to those of the display device 1 described with reference to FIGS. 1 to 15 and repeated descriptions thereof are omitted (e.g., not repeated).

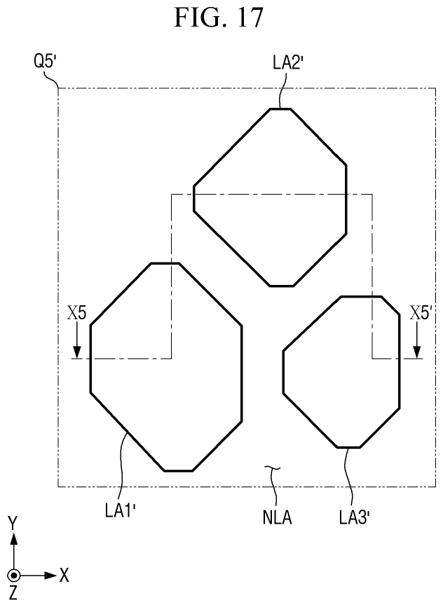

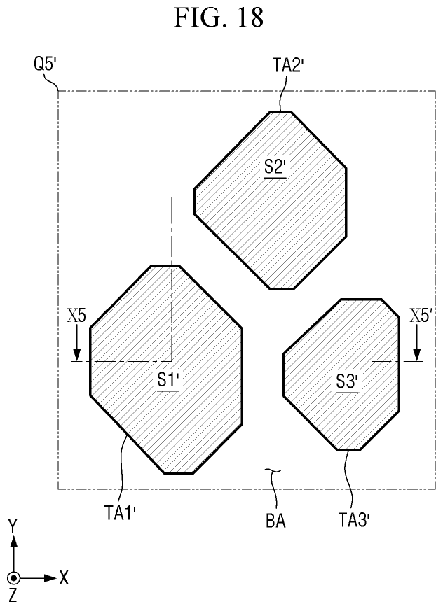

FIG. 16 is a plan view of a display device according to some embodiments of the present disclosure. FIG. 17 is an enlarged plan view of portion Q5′ of FIG. 16, more specifically, a plan view of a display substrate included in the display device of FIG. 16. FIG. 18 is an enlarged plan view of portion Q5′ of FIG. 16, more specifically, a plan view of a color conversion substrate included in the display device of FIG. 16. FIG. 19 is a cross-sectional view of the display device according to some embodiments of the present disclosure, taken along the line X5-X5′ of FIGS. 17 and 18.

Referring to FIGS. 16 to 19, each of a first light-transmitting area TA1′, a second light-transmitting area TA2′, and a third light-transmitting area TA3′ of the display device 2 according to the present embodiment may be of an irregular shape in a plan view. However, embodiments of the present disclosure are not limited thereto, and each of the first light-transmitting area TA1′, the second light-transmitting area TA2′, and the third light-transmitting area TA3′ may have a circular shape, an elliptical shape, or other suitable polygonal shapes in a plan view. Planar shapes of a first emission area LA1′, a second emission area LA2′, and a third emission area LA3′ of the display device 2 may be identical or similar to those of the corresponding first light-transmitting area TA1′, the corresponding second light-transmitting area TA2′, and the corresponding third light-transmitting area TA3′, respectively. The light-transmitting areas TA1′, TA2′, and TA3′ of a color conversion substrate 30 of the display device 2 may have set or predetermined areas S1′, S2′, and S3′, respectively.

The color gamut of the display device 2 according to the present embodiment may be preset to 83.7 to 84.1 in a BT2020 region. In some embodiments, the color gamut (%) of the display device 2 may be preset to 99.4 in a DCI region. In order to set the color gamut (%) of the display device 2 to 83.7 to 84.1, color filters 231, 233, and 235 of the display device 2 may be configured to have set or predetermined thicknesses t1′, t2′, and t3′, respectively. In some embodiments, the thickness t1′ of the first color filter 231 may be greater than each of the thickness t2′ of the second color filter 233 and the thickness t3′ of the third color filter. In some embodiments, the thickness t1′ of the first color filter 231 may be 3.0 μm to 3.4 μm, the thickness t2′ of the second color filter 233 may be 2.1 μm to 2.5 μm, and the thickness t3′ of the third color filter 235 may be 2.1 μm to 2.5 μm.

In some embodiments, the display device 2 has a reflected color satisfying neutral black when the display device 2 is not driven, and has a color difference ΔEab of 3 or less. The reflected color has a color difference ΔEab of 3 or less, which is measured by a spectrochromometer, and the color difference ΔEab is calculated by Equation 1 described above.

According to the present embodiment, as will be described with reference to FIG. 20 in more detail, a reflectance (%) of the light of the first color at 460 nm, at which the conditions are satisfied that the color difference ΔEab is 3 or less, as well as the reflected color viewed when the display device 2 is not driven satisfies neutral black, may be 1.8 to 2.2, a reflectance (%) of the light of the second color at 540 nm at which the above conditions are satisfied may be 1.7 to 2.3, and a reflectance (%) of the light of the third color at 640 nm at which the same conditions are satisfied may be 2.8 to 3.8.

According to the present embodiment, as will be described with reference to FIG. 22 in more detail, the reflectance ratio (%) of the light of the first color, the reflectance ratio (%) of the light of the second color, and the reflectance ratio (%) of the light of the third color, at each of which the conditions are satisfied that a color difference ΔEab is 3 or less, as well as the reflected color viewed when the display device 2 is not driven satisfies neutral black, may be 5.1 to 8.0, 70.0 to 74.3, and 18.5 to 23.7, respectively.

Here, 5.1 to 8.0, 70.0 to 74.3, and 18.5 to 23.7, which are obtained as, respectively, the reflectance ratio (%) of the light of the first color, the reflectance ratio (%) of the light of the second color, and the reflectance ratio (%) of the light of the third color, at each of which the conditions are satisfied that a color difference ΔEab is 3 or less, as well as the reflected color viewed when the display device 2 is not driven satisfies neutral black, may be calculated from the derived reflectance ratio (%) of the light of the first color, the derived reflectance ratio (%) of the light of the second color, and the derived reflectance ratio (%) of the light of the third color, respectively, by taking into account the visibility curve (see FIG. 21).

The reflectance of each color of the reflective light and/or the reflectance ratio of each color of the reflective light for the reflected color that satisfies neutral black when the display device 1 is not driven will be described in greater detail below.

FIG. 20 is a graph showing an SCI reflectance (%) according to a wavelength. FIG. 21 is a graph of a visibility curve. FIG. 22 is a graph obtained by applying the visibility curve of FIG. 21 to the graph of FIG. 20.

Description will be made with reference to FIGS. 20 to 22 in conjunction with Tables 1 to 7 below and FIGS. 1 to 19.

In FIGS. 20 to 22, the horizontal axis represents a wavelength (nm). In FIGS. 20 and 22, the vertical axis represents a reflectance (%), and in FIG. 21, the vertical direction represents the intensity of light. Two samples are illustrated in FIGS. 20 and 22, and Table 1. A first sample #1 relates to the display device 1 of FIG. 2. A second sample #2 relates to the display device 2 of FIG. 16. “Target” in FIGS. 20, 22, and Table 1 represents a median value between the values of the first sample #1 and the second sample #2 in interpreting the graphs of FIGS. 20 and 22. Tables 2 to 4 show the reflectance ratios of the reflective light of the first sample #1, and Tables 5 to 7 show the reflectance ratios of the reflective light of the second sample #2.

TABLE 1

| | Target | #1 | #2 |
|---|---|---|---|
| 460 nm | 2.02 | 1.84 | 2.19 |
| 540 nm | 2.01 | 1.71 | 2.30 |
| 640 nm | 3.27 | 2.75 | 3.78 |

Referring to FIGS. 20, 22, and Table 1, it can be seen that a reflectance (%) of light of the first color at 460 nm, at which conditions are satisfied that the reflected color viewed when the first sample #1 is not driven satisfies neutral black, as well as a color difference ΔEab is 3 or less, is 1.84, a reflectance (%) of light of the second color at 540 nm is 1.71, and a reflectance (%) of light of the third color at 640 nm is 2.75. Also, it can be seen that a reflectance (%) of the light of the first color at 460 nm, at which the conditions are satisfied that the reflected color viewed when the second sample #2 is not driven satisfies neutral black, as well as a color difference ΔEab is 3 or less, is 2.19, a reflectance (%) of light of the second color at 540 nm is 2.30, and a reflectance (%) of light of the third color at 640 nm is 3.78. Further, it can be seen that a median value Target of the reflectances (%) of the light of the first color at 460 nm, at which the conditions are satisfied that the reflected color satisfies neutral black when the first sample #1 and the second sample #2 are not driven, as well as the color difference ΔEab is 3 or less, a median value Target of the reflectances (%) of the light of the second color at 540 nm, and a median value Target of the reflectances (%) of the light of the third color at 640 nm are 2.19, 2.30, and 3.78, respectively.

Based on the median value Target of the reflectances (%) of the light of the first color at 460 nm, the median value Target of the reflectances (%) of the light of the second color at 540 nm, and the median value Target of the reflectances (%) of the light of the third color at 640 nm, a range of the reflectance (%) of the light of the first color at 460 nm, at which the conditions are satisfied that the reflected color satisfies neutral black when the first sample #1 and the second sample #2 are not driven, as well as the color difference ΔEab is 3 or less, a range of the reflectance (%) of the light of the second color at 540 nm at which the above conditions are satisfied, and a range of the reflectance (%) of the light of the third color at 640 nm at which the above conditions are satisfied may be 1.8 to 2.2, 1.7 to 2.3, and 2.8 to 3.8, respectively. The range of the reflectance (%) of the light of the first color at 460 nm, at which the conditions are satisfied that the reflected color satisfies neutral black when the first sample #1 and the second sample #2 are not driven, as well as the color difference ΔEab is 3 or less, the range of the reflectance (%) of the light of the second color at 540 nm at which the above conditions are satisfied, and the range of the reflectance (%) of the light of the third color at 640 nm at which the above conditions are satisfied are obtained by applying ±0.2%, ±0.3%, and ±0.3% (hereinafter, referred to as “reflectance margin errors”), respectively, to the median value Target of the reflectances (%) of the light of the first color at 460 nm, the median value Target of the reflectances (%) of the light of the second color at 540 nm, and the median value Target of the reflectances (%) of the light of the third color at 640 nm. The range of the reflectance (%) of the light of the first color at 460 nm at which the color difference ΔEab is 3 or less, the range of the reflectance (%) of the light of the second color at 540 nm at which the color difference ΔEab is 3 or less, and the range of the reflectance (%) of the light of the third color at 640 nm at which the color difference ΔEab is 3 or less are within the reflectance margin errors with respect to the median value Target of the reflectances (%) of the light of the first color at 460 nm, the median value Target of the reflectances (%) of the light of the second color at 540 nm, and the median value Target of the reflectances (%) of the light of the third color at 640 nm. Accordingly, the reflected colors of the first sample #1 and the second sample #2 may satisfy neutral black when the first sample #1 and the second sample #2 are not driven, as well as the color difference ΔEab is 3 or less.

The reflectance ratio (%) of the light of the first color, the reflectance ratio (%) of the light of the second color, and the reflectance ratio (%) of the light of the third color shown in FIG. 22 and Tables 2 to 4 may be calculated based on the graph of FIG. 20 by taking into account the visibility curve of FIG. 21. The visibility curve of FIG. 21 shows that light emitted from a specific light source is multiplied by the brightness sensation (e.g., perception) of the human eye at each wavelength, and is representative of a visibility ratio for other wavelengths by setting the visibility of the wavelength (nm) of 555 nm to 1 as the maximum sensitivity of the human eye. Referring to FIG. 22 and Tables 2 to 4, it can be seen that the reflectance ratio (%) of the light of the first color at which the reflected color viewed when the first sample #1 is not driven satisfies neutral black, as well as the color difference ΔEab satisfies 3 or less, the reflectance ratio (%) of the light of the second color at which the above conditions are satisfied, and the reflectance ratio (%) of the light of the third color are 5.3 to 9.2, 67.6 to 73.6, and 18.3 to 24.7, respectively. To be more specific, when the reflectance ratio (%) of the light of the first color is outside the range of 5.3 to 9.3, the reflected color viewed when the first sample #1 is not driven does not satisfy neutral black and the color difference ΔEab exceeds 3. Also, when the reflectance ratio (%) of the light of the second color is outside the range of 67.6 to 73.6, the reflected color viewed when the first sample #1 is not driven does not satisfy neutral black, as well as the color difference ΔEab exceeds 3, and when the reflectance ratio (%) of the light of the third color is outside the range of 18.3 to 24.7, the reflected color viewed when the first sample #1 is not driven does not satisfy neutral black and the color difference ΔEab exceeds 3.

TABLE 2

| | Reflectance | | | | | |
|---|---|---|---|---|---|---|
| | B | R | G | ΔEab | G/B | R/B |
| Blue Max | 9.2% | 68.9% | 22.0% | 2.99 | 7.5 | 2.4 |
| Blue Min | 5.3% | 71.8% | 22.9% | 2.99 | 13.6 | 4.3 |

TABLE 3

| | Reflectance | | | | | |
|---|---|---|---|---|---|---|
| | B | R | G | ΔEab | G/B | R/B |
| Green Max | 6.6% | 73.6% | 19.8% | 2.99 | 11.2 | 3.0 |
| Green Min | 8.1% | 67.6% | 24.3% | 2.99 | 8.4 | 3.0 |

TABLE 4

| | Reflectance | | | | | |
|---|---|---|---|---|---|---|
| | B | R | G | ΔEab | G/B | R/B |
| Red Max | 7.2% | 68.1% | 24.7% | 2.99 | 9.4 | 3.4 |
| Red Min | 7.8% | 73.9% | 18.3% | 2.99 | 9.4 | 2.3 |

Further, through FIG. 22 and Tables 2 to 4, the ratio between the reflectance (%) of the light of the second color and the reflectance (%) of the light of the first color, and the ratio between the reflectance (%) of the light of the third color and the reflectance (%) of the first color may be derived, respectively.

It is confirmed that the ratio (G/B) between the reflectance (%) of the light of the third color and the reflectance (%) of the light of the second color is 1:7.5 to 1:13.6, and it is confirmed that the ratio (R/B) between the reflectance (%) of the light of the third color and the reflectance (%) of the light of the first color is 1:2.3 to 1:4.3. That is, the ratio (G/B) between the reflectance (%) of the light of the third color and the reflectance (%) of the light of the second color is in the range of 1:7.5 to 1:13.6 and the ratio (R/B) between the reflectance (%) of the light of the third color and the reflectance (%) of the light of the first color is in the range of 1:2.3 to 1:4.3, so that the reflected color viewed when the first sample #1 is not driven can satisfy neutral black, as well as the color difference ΔEab can satisfy 3 or less.

Referring to FIG. 22 and Tables 5 to 7, the reflectance ratio (%) of the light of the first color, the reflectance ratio (%) of the light of the second color, and the reflectance ratio (%) of the light of the third color, at each of which the conditions are satisfied that a color difference ΔEab is 3 or less, as well as the reflected color viewed when the second sample #2 is not driven satisfies neutral black, may be 5.1 to 8.0, 70.0 to 74.3, and 18.5 to 23.7, respectively. To be more specific, when the reflectance ratio (%) of the light of the first color is outside the range of 5.1 to 8.0, the reflected color viewed when the second sample #2 is not driven does not satisfy neutral black and the color difference ΔEab exceeds 3. Also, when the reflectance ratio (%) of the light of the second color is outside the range of 70.0 to 74.3, the reflected color viewed when the second sample #2 is not driven does not satisfy neutral black, as well as the color difference ΔEab exceeds 3, and when the reflectance ratio (%) of the light of the third color is outside the range of 18.5 to 23.7, the reflected color viewed when the second sample #2 is not driven does not satisfy neutral black and the color difference ΔEab exceeds 3.

TABLE 5

| | Reflectance | | | | | |
|---|---|---|---|---|---|---|
| | B | R | G | ΔEab | G/B | R/B |
| Blue Max | 8.0% | 70.2% | 21.8% | 2.99 | 8.8 | 2.7 |
| Blue Min | 5.1% | 72.4% | 22.5% | 2.99 | 14.3 | 4.4 |

TABLE 6

| | Reflectance | | | | | |
|---|---|---|---|---|---|---|
| | B | R | G | ΔEab | G/B | R/B |
| Green Max | 5.9% | 74.3% | 19.8% | 2.99 | 12.6 | 3.4 |
| Green Min | 6.9% | 70.0% | 23.1% | 2.99 | 10.2 | 3.4 |

TABLE 7

| | Reflectance | | | | | |
|---|---|---|---|---|---|---|
| | B | R | G | ΔEab | G/B | R/B |
| Red Max | 6.5% | 69.8% | 23.7% | 2.99 | 10.8 | 3.7 |
| Red Min | 6.9% | 74.6% | 18.5% | 2.99 | 10.8 | 2.7 |

Further, through FIG. 22 and Tables 5 to 7, the ratio between the reflectance (%) of the light of the second color and the reflectance (%) of the light of the first color, and the ratio between the reflectance (%) of the light of the third color and the reflectance (%) of the first color may be derived, respectively.

It is confirmed that the ratio (G/B) between the reflectance (%) of the light of the third color and the reflectance (%) of the light of the second color is 1:8.8 to 1:14.3, and it is confirmed that the ratio (R/B) between the reflectance (%) of the light of the third color and the reflectance (%) of the light of the first color is 1:2.7 to 1:4.4. That is, the ratio (G/B) between the reflectance (%) of the light of the third color and the reflectance (%) of the light of the second color is in the range of 1:8.8 to 1:14.3 and the ratio (R/B) between the reflectance (%) of the light of the third color and the reflectance (%) of the light of the first color is in the range of 1:2.7 to 1:4.4, so that the reflected color viewed when the second sample #2 is not driven can satisfy neutral black, as well as the color difference ΔEab can satisfy 3 or less.

As described above, by determining the areas of the color filters 231, 233, and 235 (or the areas S1, S2, and S3 of the light-transmitting areas TA1, TA2, and TA3) and the areas of the color filters 231, 233, 235 (or the areas S1′, S2′, S3′ of the light-transmitting areas TA1′, TA2′, and TA3′), it is possible to derive (e.g., obtain) the reflected colors and the color difference ΔEab which satisfy neutral black when the samples #1 and #2 are not driven. That is, in the case of the first sample #1, the ratio (S2/S3) of the area S3 of the third light-transmitting area TA3 to the area S2 of the second light-transmitting area TA2 ranges from 1.3 to 2.1, and the ratio (S1/S3) of the area S3 of the third light-transmitting area TA3 to the area S1 of the first light-transmitting area TA1 ranges from 0.8 to 1.7, so that the above-described reflected color and color difference ΔEab satisfying neutral black of the first sample #1 can be derived.

Furthermore, in the case of the second sample #2, the ratio (S2′/S3′) of the area S3′ of the third light-transmitting area TA3′ to the area S2′ of the second light-transmitting area TA2′ ranges from 1.3 to 1.9, and the ratio (S1′/S3′) of the area S3′ of the third light-transmitting area TA3′ to the area S1′ of the first light-transmitting area TA1′ ranges from 1.1 to 1.9, so that the above-described reflected color and color difference ΔEab satisfying neutral black of the second sample #2 can be derived.

According to embodiments of the present disclosure, a display device capable of realizing a neutral black reflection color can be provided.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

However, the effects of the embodiments are not restricted to the one set forth herein. The above and other effects of the embodiments will become more apparent to one of daily skill in the art to which the embodiments pertain by referencing the claims, and equivalents thereof.

1. A display device comprising:
a first substrate comprising a first emission area, a second emission area, and a third emission area;
a first wavelength conversion pattern overlapping the first emission area;
a second wavelength conversion pattern overlapping the second emission area;
a light-transmitting pattern overlapping the third emission area;
a first color filter on the first wavelength conversion pattern;
a second color filter on the second wavelength conversion pattern; and
a third color filter on the light-transmitting pattern,
wherein reflected light caused by a measurement light source emitted to the first substrate comprises light of a first color having a wavelength in a range from 380 nm to 500 nm, light of a second color having a wavelength in a range from 500 nm to 600 nm, and light of a third color having a wavelength in a range from 600 nm to 780 nm, and
wherein a reflectance ratio (%) of the light of the first color, a reflectance ratio (%) of the light of the second color, and a reflectance ratio (%) of the light of the third color, which are measured in a specular component included (SCI) mode, are 5.3 to 9.2, 67.6 to 73.6, and 18.3 to 24.7, respectively.

2. The display device of claim 1, wherein a thickness of the first color filter is greater than a thickness of the second color filter and the thickness of the second color filter is greater than a thickness of the third color filter.

3. The display device of claim 2, wherein the thickness of the first color filter is 4.0 μm to 4.4 μm.

4. The display device of claim 3, wherein the thickness of the second color filter is 3.0 μm to 3.4 μm.

5. The display device of claim 4, wherein the thickness of the third color filter is 2.8 μm to 3.2 μm.

6. The display device of claim 1, wherein a color gamut (%) of the display device is 90.2 to 90.6 in a BT2020 region.

7. The display device of claim 1, wherein the reflectance ratio (%) of the light of the first color, the reflectance ratio (%) of the light of the second color, and the reflectance ratio (%) of the light of the third color are calculated further based on a visibility curve.

8. The display device of claim 1, wherein a ratio between a reflectance of the light of the first color and a reflectance of the light of the second color is 1:7.5 to 1:13.6.

9. The display device of claim 1, wherein a ratio between a reflectance of the light of the first color and a reflectance of the light of the third color is 1:2.3 to 1:4.3.

10. The display device of claim 1, further comprising a second substrate opposed to the first substrate and comprising a first light-transmitting area overlapping the first emission area, a second light-transmitting area overlapping the second emission area, and a third light-transmitting area overlapping the third emission area,
wherein a ratio in area of the third light-transmitting area to the second light-transmitting area is in a range of 1.3 to 2.1 and a ratio in the area of the third light-transmitting area to the first light-transmitting area is in a range of 0.8 to 1.7.

11. The display device of claim 1, wherein a reflected color of the reflected light has a color difference ΔEab of 3 or less, which is measured by a spectrochromometer, and the color difference ΔEab is calculated by Equation 1 below:
ΔEab={(ΔL*)2+(Δa*)2+(Δb*)2}1/2 (1)
where L*, a*, and b* are colorimetric values in CIE 1931 space measured utilizing the spectrochromometer under conditions of an illuminant C and 2° viewing angle.

12. The display device of claim 1, wherein the measurement light source comprises standard illuminant C, or D65.

13. A display device comprising:
a first substrate comprising a first emission area, a second emission area, and a third emission area, each of which is to emit a first light;
a second substrate having a first surface facing the first substrate and on which a first light-transmitting area overlapping the first emission area, a second light-transmitting area overlapping the second emission area, and a third light-transmitting area overlapping the third emission area are defined, and a second surface opposite to the first surface;
a first color filter on the first surface of the second substrate and overlapping the first light-transmitting area;
a second color filter on the first surface of the second substrate and overlapping the second light-transmitting area;
a third color filter on the first surface of the second substrate and overlapping the third light-transmitting area;
a first wavelength conversion pattern on the first color filter;
a second wavelength conversion pattern on the second color filter; and
a light-transmitting pattern on the third color filter,
wherein reflected light caused by a measurement light source emitted to the first substrate from a side of the second surface comprises light of a first color having a wavelength ranging from 380 nm to 500 nm, light of a second color having a wavelength ranging from 500 nm to 600 nm, and light of a third color having a wavelength ranging from 600 nm to 780 nm,
wherein a thickness of the first color filter is greater than a thickness of the second color filter and the thickness of the first color filter is greater than a thickness of the third color filter,
wherein a reflectance ratio (%) of the light of the first color, a reflectance ratio (%) of the light of the second color, and a reflectance ratio (%) of the light of the third color, which are measured in a specular component included (SCI) mode, are 5.1 to 8.0, 70.0 to 74.3, and 18.5 to 23.7, respectively,
wherein a reflected color of the reflected light has a color difference ΔEab of 3 or less, which is measured by a spectrochromometer, and the color difference ΔEab is calculated by Equation 1 below:
ΔEab={(ΔL*)2+(Δa*)2+(Δb*)2}1/2 (1)
where L*, a*, and b* are colorimetric values in CIE 1931 space measured utilizing the spectrochromometer under conditions of an illuminant C and 2° viewing angle.

14. The display device of claim 13, wherein the thickness of the first color filter is 3.0 μm to 3.4 μm.

15. The display device of claim 14, wherein the thickness of the second color filter is 2.1 μm to 2.5 μm.

16. The display device of claim 15, wherein the thickness of the third color filter is 2.1 μm to 2.5 μm.

17. The display device of claim 13, wherein a color gamut (%) of the display device is 83.7 to 84.1 in a BT2020 region.

18. The display device of claim 13, wherein the reflectance ratio (%) of the light of the first color, the reflectance ratio (%) of the light of the second color, and the reflectance ratio (%) of the light of the third color are calculated further based on a visibility curve.

19. The display device of claim 13, wherein a ratio between a reflectance of the light of the second color and a reflectance of the light of the first color is 1:8.8 to 1:14.3.

20. The display device of claim 19, wherein a ratio between a reflectance of the light of the third color and a reflectance of the light of the first color is 1:2.7 to 1:4.4.

21. The display device of claim 13, wherein a ratio in area of the third light-transmitting area to the second light-transmitting area is in a range of 1.3 to 1.9 and a ratio in area of the third light-transmitting area to the first light-transmitting area is in a range of 1.1 to 1.9.

22. A display device comprising:
a first substrate comprising a first emission area, a second emission area, and a third emission area, each of which is to emit a first light;
a second substrate having a first surface facing the first substrate and on which a first light-transmitting area overlapping the first emission area, a second light-transmitting area overlapping the second emission area, and a third light-transmitting area overlapping the third emission area are defined, and a second surface opposite to the first surface;
a first color filter on the first surface of the second substrate and overlapping the first light-transmitting area;
a second color filter on the first surface of the second substrate and overlapping the second light-transmitting area;
a third color filter on the first surface of the second substrate and overlapping the third light-transmitting area;
a first wavelength conversion pattern on the first color filter;
a second wavelength conversion pattern on the second color filter; and
a light-transmitting pattern on the third color filter,
wherein reflected light caused by a measurement light source emitted to the first substrate from a side of the second surface comprises light of a first color having a wavelength ranging from 380 nm to 500 nm, light of a second color having a wavelength ranging from 500 nm to 600 nm, and light of a third color having a wavelength ranging from 600 nm to 780 nm,
wherein a reflectance (%) of the light of the first color at 460 nm, a reflectance (%) of the light of the second color at 540 nm, and a reflectance (%) of the light of the third color at 640 nm, which are measured in a specular component included (SCI) mode, are 1.8 to 2.2, 1.7 to 2.3, and 2.8 to 3.8, respectively,
wherein a reflected color of the reflected light has a color difference ΔEab of 3 or less, which is measured by a spectrochromometer, and the color difference ΔEab is calculated by Equation 1 below:
ΔEab={(ΔL*)2+(Δa*)2+(Δb*)2}1/2 (1)
where L*, a*, and b* are colorimetric values in CIE 1931 space measured utilizing the spectrochromometer under conditions of an illuminant C and 2° viewing angle.

23. The display device of claim 22, wherein a thickness of the first color filter is greater than a thickness of the second color filter and the thickness of the second color filter is greater than a thickness of the third color filter.

24. The display device of claim 22, wherein a thickness of the first color filter is 4.0 μm to 4.4 μm, a thickness of the second color filter is 3.0 μm to 3.4 μm, and a thickness of the third color filter is 2.8 μm to 3.2 μm.

25. The display device of claim 22, wherein a thickness of the first color filter is greater than a thickness of the second color filter and the thickness of the first color filter is greater a thickness of the third color filter.

26. The display device of claim 22, wherein a thickness of the first color filter is 3.0 μm to 3.4 μm, a thickness of the second color filter is 2.1 μm to 2.5 μm, and a thickness of the third color filter is 2.1 μm to 2.5 μm.
